(19) United States
(12) Patent Application Publication
(10) Pub. No.: US 2026/0039252 A1
(43) Pub. Date: Feb. 5, 2026

(54) POWER AMPLIFICATION DEVICE

(71) Applicant: Murata Manufacturing Co., Ltd., Nagaokakyo-shi (JP)

(72) Inventors: Tetsurou ASHIDA, Nagaokakyo-shi (JP); Kouhei JITOUSHO, Nagaokakyo-shi (JP); Tomoya ODA, Nagaokakyo-shi (JP); Shohei IMAI, Nagaokakyo-shi (JP)

(21) Appl. No.: 19/355,000

(22) Filed: Oct. 10, 2025

Related U.S. Application Data
(63) Continuation of application No. PCT/JP2024/014716, filed on Apr. 11, 2024.

(30) Foreign Application Priority Data
Apr. 12, 2023 (JP) 2023-065144

(51) Int. Cl. H03F 1/02; H03F 1/30; H03F 3/24

(52) U.S. Cl. CPC H03F 1/0288; H03F 1/303; H03F 3/245; H03F 2200/451

(57) ABSTRACT

A power amplification device includes a substrate, an integrated circuit, a splitter, a carrier amplifier, a peak amplifier, a first bias circuit that provides bias to the carrier amplifier, a second bias circuit that provides bias to the peak amplifier, a drive-level detector circuit that outputs a signal indicating a drive level of the carrier amplifier, based on a high-frequency signal outputted by the carrier amplifier, a detector circuit that outputs a control signal to control the second bias circuit, based on an inputted high-frequency signal and the signal indicating the drive level of the carrier amplifier, and a coupler. The detector circuit varies a threshold for the control signal. The integrated circuit includes the splitter, the carrier amplifier, the peak amplifier, the first bias circuit, the second bias circuit, the drive-level detector circuit, and the detector circuit.

### CROSS REFERENCE TO RELATED APPLICATION

This is a continuation of International Application No. PCT/JP2024/014716 filed on Apr. 11, 2024 which claims priority from Japanese Patent Application No. 2023-065144 filed on Apr. 12, 2023. The contents of these applications are incorporated herein by reference in their entireties.

### BACKGROUND OF THE DISCLOSURE

### Field of the Disclosure

The present disclosure relates to a power amplification device.

### Description of the Related Art

A Doherty amplifier is known as a highly efficient power amplifier circuit. Generally, a Doherty amplifier includes a carrier amplifier that operates regardless of the power level of the input signal and a peak amplifier that turns off when the power level of the input signal is low and turns on when the power level is high. The carrier amplifier and the peak amplifier are coupled in parallel. In this configuration, when the power level of a high frequency input signal is high, the carrier amplifier operates while maintaining saturation at its saturated output power level. As a result, the Doherty amplifier can achieve higher efficiency compared to typical power amplifier circuits.

U.S. Patent Application Publication No. 2016/0241209 Specification, U.S. Patent Application Publication No. 2020/0028472 Specification, and Japanese Unexamined Patent Application Publication No. 2019-41277 describe techniques to control the bias of the peak amplifier.

The technique described in U.S. Patent Application Publication No. 2016/0241209 Specification detects saturation of the carrier amplifier using the bias circuit for the carrier amplifier and controls the bias circuit for the peak amplifier based on the detection signal.

The technique described in U.S. Patent Application Publication No. 2020/0028472 Specification detects saturation of the carrier amplifier using the output signal of the carrier amplifier and controls the bias circuit for the peak amplifier based on the detection signal.

The technique described in Japanese Unexamined Patent Application Publication No. 2019-41277 controls the bias circuit for the peak amplifier based on the level of the high frequency input signal inputted to the Doherty amplifier or the level of the high frequency input signal inputted to the carrier amplifier.

### BRIEF SUMMARY OF THE DISCLOSURE

In the techniques described in U.S. Patent Application Publication No. 2016/0241209 Specification and U.S. Patent Application Publication No. 2020/0028472 Specification, it takes about several tens of nanoseconds for the circuit that detects saturation of the carrier amplifier to respond. Therefore, the following inconveniences can occur. For example, when a high frequency input signal with instantaneous power increases (much shorter than several tens of nanoseconds) is inputted to the Doherty amplifier, periods during which the carrier amplifier is saturated may occur within several tens of nanoseconds between the time the carrier amplifier starts saturating and the time the bias point of the peak amplifier changes. This can result in degradation in the quality of the high frequency output signal of the Doherty amplifier. When such a Doherty amplifier is used in a communication device, there is a risk that high communication quality cannot be maintained.

The technique described in Japanese Unexamined Patent Application Publication No. 2019-41277 operates based on the high frequency input signal level. However, this technique detects the high frequency input signal level using a bias circuit, and the response time is basically considered to be slow. This can lead to degradation in the quality of the high frequency output signal of the Doherty amplifier.

The present disclosure has been made in the light of the matters described above, and a possible benefit of the present disclosure is to suppress the degradation in the quality of high frequency output signals.

A power amplification device according to an aspect of the present disclosure includes a substrate, an integrated circuit provided on a major surface of the substrate, a splitter, a carrier amplifier that amplifies an inputted high-frequency signal, a peak amplifier that amplifies an inputted high-frequency signal, a first bias circuit that provides bias to the carrier amplifier, a second bias circuit that provides bias to the peak amplifier, a drive-level detector circuit that outputs a signal indicating a drive level of the carrier amplifier, based on a high-frequency signal outputted by the carrier amplifier, a detector circuit that outputs a control signal to control the second bias circuit, based on an inputted high-frequency signal and the signal indicating the drive level of the carrier amplifier, and a coupler provided on the major surface of the substrate. The detector circuit varies a threshold for the control signal based on the inputted high-frequency signal and the signal indicating the drive level of the carrier amplifier. The integrated circuit includes the splitter, the carrier amplifier, the peak amplifier, the first bias circuit, the second bias circuit, the drive-level detector circuit, and the detector circuit, which are provided at different positions when viewed in a direction perpendicular to the major surface of the substrate. When viewed in the direction perpendicular to the major surface of the substrate, a placement region of the drive-level detector circuit is adjacent to a placement region where an amplifier of the carrier amplifier is arranged.

A power amplification device according to an aspect of the present disclosure includes a substrate, an integrated circuit provided on a major surface of the substrate, a splitter, a carrier amplifier that amplifies an inputted high-frequency signal, a peak amplifier that amplifies an inputted high-frequency signal, a first bias circuit that provides bias to the carrier amplifier, a second bias circuit that provides bias to the peak amplifier, a drive-level detector circuit that outputs a signal indicating a drive level of the carrier amplifier, based on a high-frequency signal outputted by the carrier amplifier, a detector circuit that outputs a control signal to control the peak amplifier, based on an inputted high-frequency signal and the signal indicating the drive level of the carrier amplifier, and a coupler provided on the major surface of the substrate. The detector circuit varies a threshold for the control signal based on the inputted high-frequency signal and the signal indicating the drive level of the carrier amplifier. The integrated circuit includes the splitter, the carrier amplifier, the peak amplifier, the first bias circuit, the second bias circuit, the drive-level detector circuit, and the detector circuit, which are provided at different positions when viewed in a direction perpendicular to the major surface of the substrate. When viewed in the direction perpendicular to the major surface of the substrate, a placement region of the drive-level detector circuit is adjacent to a placement region where an amplifier of the carrier amplifier is arranged.

A power amplification device according to an aspect of the present disclosure includes a substrate, an integrated circuit provided on a major surface of the substrate, a splitter, a carrier amplifier that amplifies an inputted high-frequency signal, a peak amplifier that amplifies an inputted high-frequency signal, a first bias circuit that provides bias to the carrier amplifier, a second bias circuit that provides bias to the peak amplifier, a drive-level detector circuit that outputs a signal indicating a drive level of the carrier amplifier, based on a high-frequency signal outputted by the first bias circuit, a control circuit, and a coupler provided on the major surface of the substrate. The integrated circuit includes the splitter, the carrier amplifier, the peak amplifier, the first bias circuit, the second bias circuit, the drive-level detector circuit, and the control circuit, which are provided at different positions when viewed in a direction perpendicular to the major surface of the substrate. The control circuit includes a detector circuit that outputs a control signal to control the second bias circuit, and a variable attenuator that outputs to the detector circuit, based on the high-frequency signal inputted to the carrier amplifier and the signal indicating the drive level of the carrier amplifier, a high-frequency signal obtained by attenuating the inputted high-frequency signal. When viewed in the direction perpendicular to the major surface of the substrate, a placement region of the drive-level detector circuit is adjacent to a placement region where an amplifier of the carrier amplifier is arranged.

A power amplification device according to an aspect of the present disclosure includes a substrate, an integrated circuit provided on a major surface of the substrate, a splitter, a carrier amplifier that amplifies an inputted high-frequency signal, a peak amplifier that amplifies an inputted high-frequency signal, a first bias circuit that provides bias to the carrier amplifier, a second bias circuit that provides bias to the peak amplifier, a drive-level detector circuit that outputs a signal indicating a drive level of the carrier amplifier, based on a high-frequency signal outputted by the first bias circuit, a control circuit, and a coupler provided on the major surface of the substrate. The integrated circuit includes the splitter, the carrier amplifier, the peak amplifier, the first bias circuit, the second bias circuit, the drive-level detector circuit, and the control circuit, which are provided at different positions when viewed in a direction perpendicular to the major surface of the substrate. The control circuit includes a detector circuit that outputs a control signal to control the peak amplifier, and a variable attenuator that outputs to the detector circuit, based on the high-frequency signal inputted to the carrier amplifier and the signal indicating the drive level of the carrier amplifier, a high-frequency signal obtained by attenuating the inputted high-frequency signal. When viewed in the direction perpendicular to the major surface of the substrate, a placement region of the drive-level detector circuit is adjacent to a placement region where an amplifier of the carrier amplifier is arranged.

According to the present disclosure, it is possible to suppress the degradation in the quality of high-frequency output signals.

### BRIEF DESCRIPTION OF THE SEVERAL VIEWS OF THE DRAWINGS

FIG. 1 illustrates a circuit configuration of a power amplification device according to a first embodiment.

FIG. 2 is a schematic diagram illustrating an example of the relationship between high-frequency signal power of a power amplifier circuit of the first embodiment and signals outputted by a detector circuit.

FIG. 3 illustrates a specific example of the detector circuit and a drive-level detector circuit in the power amplifier circuit of the first embodiment.

FIG. 4 illustrates an equivalent circuit of the specific example of the detector circuit and the drive-level detector circuit in the power amplifier circuit of the first embodiment.

FIG. 5 illustrates an example of the relationship between high-frequency signal power of the power amplifier circuit of the first embodiment and bias voltage applied to a peak amplifier.

FIG. 6 is a plan view of the power amplification device according to the first embodiment.

FIG. 7 illustrates a circuit configuration of a power amplification device according to a second embodiment.

FIG. 8 illustrates a specific example of a detector circuit and a variable attenuator in a power amplifier circuit according to the second embodiment.

FIG. 9 is a plan view of the power amplification device according to the second embodiment.

FIG. 10 is a plan view of a power amplification device according to a third embodiment.

FIG. 11 is a plan view of a power amplification device according to a fourth embodiment.

FIG. 12 illustrates a circuit configuration of a power amplification device according to a fifth embodiment.

FIG. 13 is a plan view of the power amplification device according to the fifth embodiment.

FIG. 14 illustrates a circuit configuration of a power amplification device according to a sixth embodiment.

FIG. 15 illustrates a circuit configuration of a peak amplifier according to the sixth embodiment.

FIG. 16 illustrates a circuit configuration of a power amplification device according to a seventh embodiment.

### DETAILED DESCRIPTION OF THE DISCLOSURE

Hereinafter, embodiments of a power amplification device of the present disclosure will be described with reference to the drawings. The embodiments are not intended to limit the present disclosure. Each embodiment is illustrative, and it is obvious that configurations illustrated in different embodiments can be partially replaced or combined with each other. In the second and subsequent embodiments, the description of the same matters as the first embodiment will be omitted, and only different points will be described. In particular, similar operational effects resulting from the same configuration will not be described repeatedly for each embodiment.

### First Embodiment

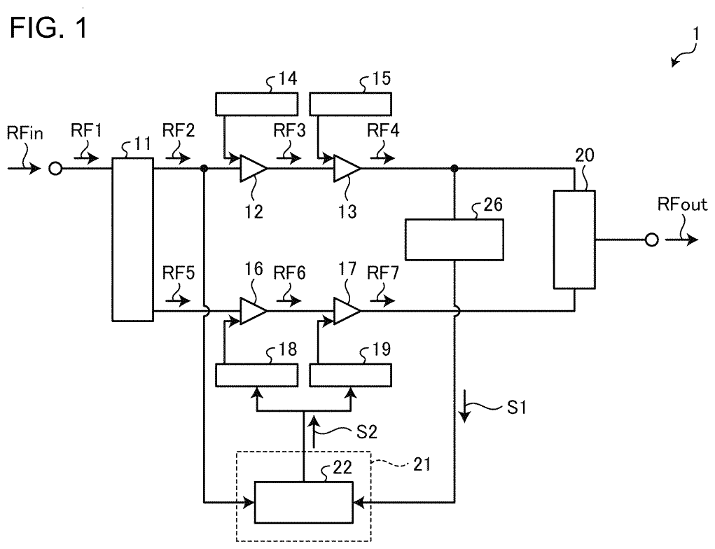

FIG. 1 illustrates a circuit configuration of a power amplification device according to a first embodiment. As illustrated in FIG. 1, a power amplification device 1 includes a Doherty amplifier. The Doherty amplifier includes a splitter 11, a first-stage (driver-stage) carrier amplifier 12, a final-stage (power-stage) carrier amplifier 13, bias circuits 14 and 15, a first-stage peak amplifier 16, a final-stage peak amplifier 17, bias circuits 18 and 19, a coupler 20, a control circuit 21, and a drive-level detector circuit 26.

The bias circuits 14 and 15 are examples of a “first bias circuit” of the present disclosure. The bias circuits 18 and 19 are examples of a “second bias circuit” of the present disclosure.

In the example illustrated in FIG. 1, the Doherty amplifier includes two stages, but the present disclosure is not limited thereto. The number of stages of the Doherty amplifier may be one, or may be three or more.

The splitter 11 splits a high-frequency signal RF1 into high-frequency signals RF2 and RF5, which differ in phase by substantially 90°. The splitter 11 outputs the high-frequency signal RF2 to the carrier amplifier 12 and outputs the high-frequency signal RF5 to the peak amplifier 16. The term “substantially 90°” includes not only a phase difference of 90° but also phase differences ranging from 45° to 135°. The high-frequency signal RF1 refers to a radio-frequency (RF) signal inputted to the power amplification device 1 (hereinafter, referred to as a “high-frequency signal RFin”). The frequency of the high-frequency signal RFin is exemplified as ranging from about several hundred megahertz (MHz) to several tens of gigahertz (GHz), but the present disclosure is not limited thereto. The high-frequency signal RF1 is the high-frequency signal RFin, which is inputted to the power amplification device 1, in the example in FIG. 1, but is not limited thereto. The high-frequency signal RF1 may be a high-frequency signal obtained by amplifying the high-frequency signal RFin using an amplifier biased by a bias circuit.

The phase of the high-frequency signal RF5 is exemplified as lagging behind that of the high-frequency signal RF2 by 90°. The power of the high-frequency signal RF5 is exemplified as being equal to that of the high-frequency signal RF2.

The carrier amplifiers 12 and 13 and the peak amplifiers 16 and 17 are amplifiers each including a plurality of transistors. The plurality of transistors included in the carrier amplifiers 12 and 13 and the peak amplifiers 16 and 17 are, for example, heterojunction bipolar transistors (HBTs), but are not limited thereto, and may be field-effect transistors (FETs).

The bias circuit 14 provides bias to the carrier amplifier 12. The bias circuit 15 provides bias to the carrier amplifier 13. The carrier amplifier 12 amplifies the high-frequency signal RF2 and outputs the resulting signal as a high-frequency signal RF3 to the carrier amplifier 13. The carrier amplifier 13 amplifies the high-frequency signal RF3 and outputs the resulting signal as a high-frequency signal RF4 to the coupler 20.

The bias circuit 18 provides bias to the peak amplifier 16. The bias circuit 19 provides bias to the peak amplifier 17. The peak amplifier 16 amplifies the high-frequency signal RF5 and outputs the resulting signal as a high-frequency signal RF6 to the peak amplifier 17. The peak amplifier 17 amplifies the high-frequency signal RF6 and outputs as a high-frequency signal RF7 to the coupler 20.

The coupler 20 couples the high-frequency signals RF4 and RF7. The coupler 20 is composed of, for example, a transformer. In the first embodiment, the coupler 20 is composed of a phase shifter, but the present disclosure is not limited thereto. The coupler 20 outputs the high-frequency signal RF4 with its phase delayed by 90°. The sum of the high-frequency signal RF7 and the output signal of the coupler 20 is a high-frequency signal RFout, which is outputted by the power amplification device 1.

The drive-level detector circuit 26 outputs a signal S1, which indicates the drive level (the operation level) of the carrier amplifier 13, to a detector circuit 22 based on the high-frequency signal RF4, which is outputted by the carrier amplifier 13.

The control circuit 21 includes the detector circuit 22.

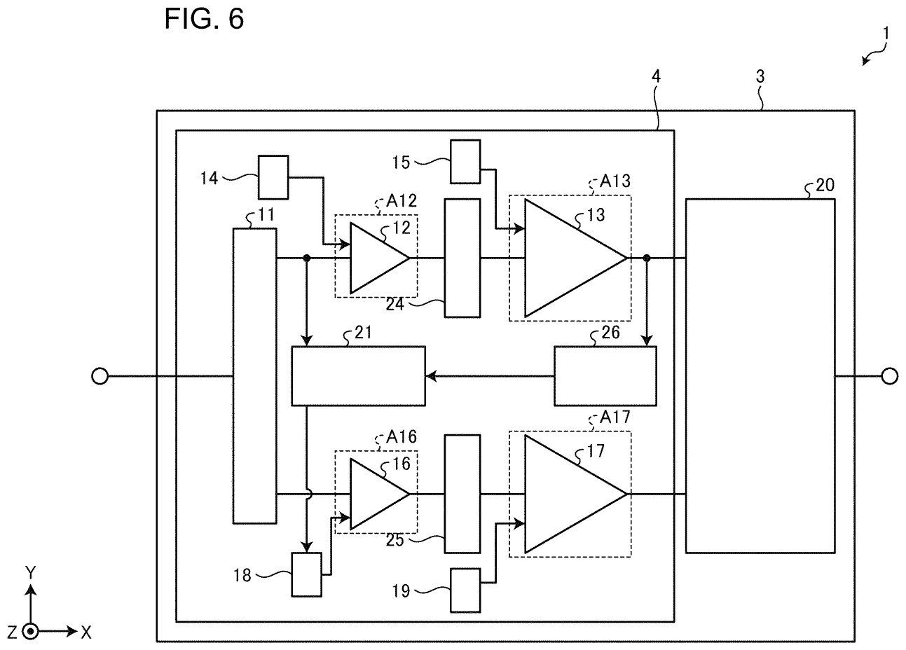

The detector circuit 22 receives the high-frequency signal RFin, which is inputted from the outside to the power amplification device 1, and the signal S1. The detector circuit 22 may receive the high-frequency signal RF1 or the high-frequency signal RF2 instead of the high-frequency signal RFin. FIG. 1 and the later-described plan view of the power amplification device 1 illustrates an example in which the high-frequency signal RF2 is inputted to the detector circuit 22 (see FIG. 6 etc.).

The detector circuit 22 outputs a signal S2, which controls the bias circuit 18, to the bias circuits 18 and 19 based on the high-frequency signal RFin and the signal S1. The bias circuit 18 provides bias to the peak amplifier 16 based on the signal S2. The bias circuit 19 provides bias to the peak amplifier 17. The signal S2 may be outputted to either the bias circuit 18 or 19. That is, the signal S2 may be outputted to at least one of the bias circuits that provide bias to the peak amplifiers.

The control circuit 21 may further include a variable attenuator. In this case, the control circuit 21 may further include another attenuator. The variable attenuator attenuates the high-frequency signal RFin or the signal outputted from the attenuator based on the signal S1. The attenuator attenuates the high-frequency signal RFin based on an external control signal and outputs the resulting signal to the variable attenuator. When the control circuit 21 includes the variable attenuator, the detector circuit 22 outputs the signal S2 based on the signal outputted from the variable attenuator.

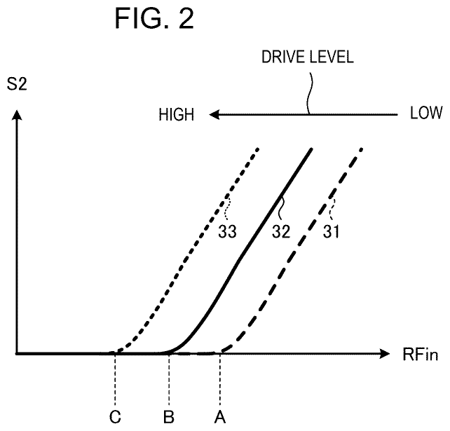

FIG. 2 is a schematic diagram illustrating an example of the relationship between high-frequency signal power of the power amplifier circuit of the first embodiment and the signal outputted by the detector circuit. In FIG. 2, the horizontal axis indicates power of the high-frequency signal RFin, and the vertical axis indicates the signal S2, which is outputted by the detector circuit 22.

The detector circuit 22 varies the rising point of the signal S2 depending on the signal S1. A waveform 31 represents the relationship between the power of the high-frequency signal RFin and the signal S2 when the drive level of the carrier amplifier 13 is relatively low. A waveform 32 represents the relationship between the power of the high-frequency signal RFin and the signal S2 when the drive level of the carrier amplifier 13 is relatively intermediate. A waveform 33 represents the relationship between the power of the high-frequency signal RFin and the signal S2 when the drive level of the carrier amplifier 13 is relatively high.

In the case where the drive level of the carrier amplifier 13 is relatively low, as represented by the waveform 31, the detector circuit 22 raises the signal S2 when the power of the high-frequency signal RFin reaches a value A. In the range where the power of the high-frequency signal RFin is greater than or equal to the value A, the detector circuit 22 increases the signal S2 as the power of the high-frequency signal RFin increases.

In the case where the drive level of the carrier amplifier 13 is relatively intermediate, as represented by the waveform 32, the detector circuit 22 raises the signal S2 when the power of the high-frequency signal RFin reaches a value B (B<A). In the range where the power of the high-frequency signal RFin is greater than or equal to the value B, the detector circuit 22 increases the signal S2 as the power of the high-frequency signal RFin increases.

In the case where the drive level of the carrier amplifier 13 is relatively high, as represented by the waveform 33, the detector circuit 22 raises the signal S2 when the power of the high-frequency signal RFin reaches a value C (C<B). In the range where the power of the high-frequency signal RFin is greater than or equal to the value C, the detector circuit 22 increases the signal S2 as the power of the high-frequency signal RFin increases.

When the inputted high-frequency signal RFin has high power, which is a main cause of saturation of the carrier amplifiers 12 and 13, the detector circuit 22 outputs the signal S2 to the bias circuits 18 and 19 and allows the bias circuits 18 and 19 to activate the peak amplifiers 16 and 17. Thus, the carrier amplifiers 12 and 13 remain essentially unsaturated.

Here, the response speed of the detector circuit 22 is important. The detector circuit 22, which detects the high-frequency signal RFin, can respond much faster than in the case where saturation of the carrier amplifier is detected using the techniques described in U.S. Patent Application Publication No. 2016/0241209 Specification and U.S. Patent Application Publication No. 2020/0028472 Specification. As a result, even if the power of the high-frequency signal RFin increases rapidly, the detector circuit 22 immediately responds and allows the bias circuits 18 and 19 to activate the peak amplifiers 16 and 17, so that the carrier amplifiers 12 and 13 are not saturated even momentarily.

When the temperature or other peripheral environments have changed (for example, the gains of the carrier amplifiers 12 and 13 have increased due to an extremely low temperature), the carrier amplifiers 12 and 13 can be saturated even if the power of the high-frequency signal RFin is low. To accommodate such cases as well, the detector circuit 22 detects the signal S1, which indicates the drive level of the carrier amplifiers 12 and 13, and when the carrier amplifiers 12 and 13 are close to saturation, immediately activates the peak amplifiers 16 and 17 even if the power of the high-frequency signal RFin is low.

Since the detector circuit 22 detects the high-frequency signal RFin, the detector circuit 22 can allow the bias circuits 18 and 19 to activate the peak amplifiers 16 and 17 without causing saturation of the carrier amplifiers 12 and 13 even if the detector circuit 22 takes time to detect the drive levels of the carrier amplifiers 12 and 13. As a result, the Doherty amplifier can suppress the degradation in the quality of the high-frequency signal RFout.

The detector circuit 22 can be regarded as operating in a feedforward manner in response to the high-frequency signal RFin, and in a feedback manner in response to the signal S1.

### (Specific Example of Detector Circuit and Drive-Level Detector Circuit)

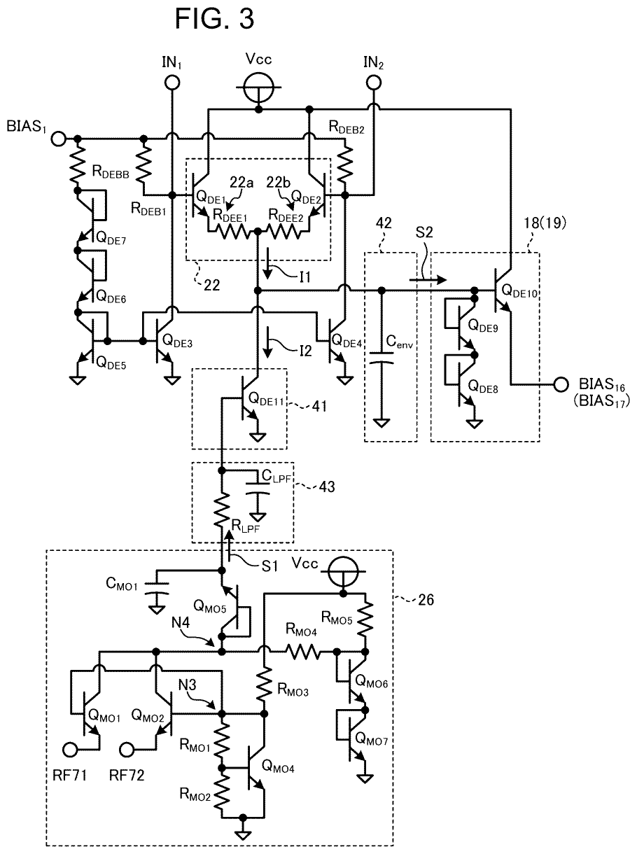

FIG. 3 illustrates a specific example of the detector circuit and the drive-level detector circuit in the power amplifier circuit of the first embodiment. FIG. 3 also illustrates a circuit element to provide bias to the detector circuit 22. A low pass filter 42 and the bias circuits 18 and 19 illustrated in FIG. 3 may be omitted. The low pass filter 42 can be omitted, for example, when a good differential signal is obtained. The bias circuits 18 and 19 can be omitted, for example, when the transistors (amplifying transistors) to be biased are small.

The detector circuit 22 includes transistors Q_{DE1} and Q_{DE2} and resistors R_{DEE1} and R_{DEE2}.

In the present disclosure, each transistor is a bipolar transistor. However, the present disclosure is not limited thereto. The bipolar transistors are exemplified as heterojunction bipolar transistors (HBTs), but the present disclosure is not limited thereto. The transistors may be, for example, field-effect transistors (FETs). The transistors may be multi-finger transistors, in which a plurality of unit transistors are electrically coupled in parallel. Each unit transistor refers to the minimum structure that constitutes a transistor.

The collector of the transistor Q_{DE1} is electrically coupled to a power supply potential Vcc. The emitter of the transistor Q_{DE1} is electrically coupled to one end of the resistor R_{DEE1}. That is, the transistor Q_{DE1} and the resistor R_{DEE1} are coupled as an emitter-follower. The transistor Q_{DE1} and the resistor R_{DEE1} constitute a first emitter-follower circuit 22a.

The detector circuit 22 may include a source-follower circuit instead of the first emitter-follower circuit 22a.

The collector of the transistor Q_{DE2} is electrically coupled to the power supply potential Vcc. The emitter of the transistor Q_{DE2} is electrically coupled to one end of the resistor R_{DEE2}. That is, the transistor Q_{DE2} and the resistor R_{DEE2} are coupled as an emitter-follower. The transistor Q_{DE2} and the resistor R_{DEE2} constitute a second emitter-follower circuit 22b.

The detector circuit 22 may include a source-follower circuit instead of the second emitter-follower circuit 22b.

The other end of the resistor R_{DEE1} and the other end of the resistor R_{DEE2} are electrically coupled. The sum of the output current of the first emitter-follower circuit 22a and the output current of the second emitter-follower circuit 22b is an output current I1 of the detector circuit 22.

Resistors R_{DEBB}, R_{DEB1}, and R_{DEB2} and transistors Q_{DE5}, Q_{DE6}, and Q_{DE7} apply bias voltage to the bases of the transistors Q_{DE1} and Q_{DE2}.

One end of the resistor R_{DEBB}, one end of the resistor R_{DEB1}, and one end of the resistor R_{DEB2} are electrically coupled.

The other end of the resistor R_{DEBB} is electrically coupled to the collector and base of the transistor Q_{DE7}. That is, the transistor Q_{DE7} is diode-coupled. The emitter of the transistor Q_{DE7} is electrically coupled to the collector and base of the transistor Q_{DE6}. That is, the transistor Q_{DE6} is diode-coupled. The emitter of the transistor Q_{DE6} is electrically coupled to the collector and base of the transistor Q_{DE5}. That is, the transistor Q_{DE5} is diode-coupled. The emitter of the transistor Q_{DE5} is electrically coupled to a reference potential. The reference potential is exemplified as ground potential, but the present disclosure is not limited thereto.

The one end of the resistor R_{DEBB}, the one end of the resistor R_{DEB1}, and the one end of the resistor R_{DEB2} receive a bias current BIAS₁. The resistor R_{DEBB} and the transistors Q_{DE7}, Q_{DE6}, and Q_{DE5} generate a constant voltage. This voltage is applied to the base of the transistor Q_{DE1} via the resistor R_{DEB1} and to the base of the transistor Q_{DE2} via the resistor R_{DEB2}.

Each of transistors Q_{DE3} and Q_{DE4} is coupled to the transistor Q_{DE5} as a current mirror. The collector of the transistor Q_{DE3} is electrically coupled to the base of the transistor Q_{DE1}. The transistor Q_{DE3} is thereby able to adjust the base current of the transistor Q_{DE1}. The collector of the transistor Q_{DE4} is electrically coupled to the base of the transistor Q_{DE2}. The transistor Q_{DE4} is thereby able to adjust the base current of the transistor Q_{DE2}.

The bases of the transistors Q_{DE1} and O_{DE2}, respectively, receive high-frequency signals IN₁ and IN₂, which are obtained by transforming the high-frequency signal RFin into a differential signal. The high-frequency signals IN₁ and IN₂ can be obtained by, for example, inputting the high-frequency signal RFin to a balun.

The other end of the resistor R_{DEE1} and the other end of the resistor R_{DEE2} are electrically coupled to a constant-current circuit 41. The constant-current circuit 41 includes a transistor Q_{DE11}. The constant-current circuit 41 serves as a current bias circuit for the detector circuit 22.

The drive-level detector circuit 26 includes resistors R_{MO1}, R_{MO2}, R_{MO3}, R_{MO4}, and R_{MO5}, transistors Q_{MO1}, Q_{MO2}, Q_{MO4}, Q_{MO5}, Q_{MO6}, and Q_{MO7}, and a capacitor C_{MO1}.

In this description, the carrier amplifier 13 is assumed to be a differential amplifier and output high-frequency signals RF71 and RF72, which constitute a pair of differential signals.

The emitter of the transistor Q_{MO1} receives the high-frequency signal RF71. The emitter of the transistor Q_{MO1} is exemplified as being electrically coupled to an output terminal (the collector or drain of the output transistor) of one of the amplifiers in the carrier amplifier 13.

The emitter of the transistor Q_{MO2} receives the high-frequency signal RF72. The emitter of the transistor Q_{MO2} is exemplified as being electrically coupled to an output terminal (the collector or drain of the output transistor) of the other amplifier in the carrier amplifier 13.

The bases of the transistors Q_{MO1} and Q_{MO2} are electrically coupled to a node N3.

The collectors of the transistors Q_{MO1} and Q_{MO2} are electrically coupled to a node N4.

The resistors R_{MO1}, R_{MO2}, and R_{MO3} and the transistor Q_{MO4} apply voltage to the node N3. That is, the resistors R_{MO1}, R_{MO2}, and R_{MO3} and the transistor Q_{MO4} provide bias to the bases of the transistors Q_{MO1} and Q_{MO2}.

One end of the resistor R_{MO3} is electrically coupled to the power supply potential Vcc. The other end of the resistor R_{MO3} is electrically coupled to the node N3, the collector of the transistor Q_{MO4}, and one end of the resistor R_{MO1}. The other end of the resistor R_{MO1} is electrically coupled to the base of the transistor Q_{MO4} and one end of the resistor R_{MO2}. The emitter of the transistor Q_{MO4} and the other end of the resistor R_{MO2} are electrically coupled to the reference potential. The resistors R_{MO1} and R_{MO2} and the transistor Q_{MO4} generate a constant voltage. This voltage is the voltage at the node N3.

The resistors R_{MO4} and R_{MO5} and the transistors Q_{MO6} and Q_{MO7} apply voltage to the node N4. That is, the resistors R_{MO4} and R_{MO5} and the transistors Q_{MO6} and Q_{MO7} provide bias to the collectors of the transistors Q_{MO1} and Q_{MO2}.

One end of the resistor R_{MO5} is electrically coupled to the power supply potential Vcc. The other end of the resistor R_{MO5} is electrically coupled to the collector and base of the transistor Q_{MO6}. That is, the transistor Q_{MO6} is diode-coupled. The emitter of the transistor Q_{MO6} is electrically coupled to the collector and base of the transistor Q_{MO7}. That is, the transistor Q_{MO7} is diode-coupled. The emitter of the transistor Q_{MO7} is electrically coupled to the reference potential. One end of the resistor R_{MO4} is electrically coupled to the other end of the resistor R_{MO5} and the collector and base of the transistor Q_{MO6}. The other end of the resistor R_{MO4} is electrically coupled to the node N4. The transistors Q_{MO6} and Q_{MO7} generate a constant voltage. This voltage is the voltage at the node N4 via the resistor R_{MO4}.

The collector and base of the transistor Q_{MO5} are electrically coupled to the node N4. That is, the transistor Q_{MO5} is diode-coupled. The emitter of the transistor Q_{MO5} is electrically coupled to one end of the capacitor C_{MO1}. The other end of the capacitor C_{MO1} is electrically coupled to the reference potential.

The transistor Q_{MO5} outputs the signal S1 from the emitter. That is, the emitter voltage of the transistor Q_{MO5} corresponds to the signal S1 in the first embodiment. The capacitor C_{MO1} shunts the high-frequency components of the signal S1, thereby smoothing the signal S1.

The resistors R_{MO1}, R_{MO2}, and R_{MO3} and the transistor Q_{MO4} only need to output an approximately constant voltage and can be regarded as a constant voltage source. The resistor Ros and the transistors Q_{MO6} and Q_{MO7} only need to output an approximately constant voltage and can be regarded as a constant voltage source. The transistor Q_{MO5} only needs to produce an approximately constant voltage drop and can be regarded as a constant voltage source.

A low pass filter 43 includes a resistor R_{LPF} and a capacitor C_{LPF}.

One end of the resistor R_{LPF} is electrically coupled to the emitter of the transistor Q_{MO5}. The other end of the resistor R_{LPF} is electrically coupled to one end of the capacitor C_{LPF}. The other end of the capacitor C_{LPF} is electrically coupled to the reference potential.

The other end of the resistor R_{LPF} and the one end of the capacitor C_{LPF} are electrically coupled to the base of the transistor Q_{DE11}. The low pass filter 43 allows the low-frequency components of the signal S1 to pass through and outputs the resulting signal to the base of the transistor Q_{DE11}.

The low pass filter 42 includes a capacitor Cₑₙᵥ. One end of the capacitor Cₑₙᵥ is electrically coupled to the other end of the resistor R_{DEE1}, the other end of the resistor R_{DEE2}, and the collector of the transistor Q_{DE11}. The other end of the capacitor Cₑₙᵥ is electrically coupled to the reference potential.

The capacitor Cₑₙᵥ is charged or discharged due to the difference between the output current I1 of the detector circuit 22 and a collector current I2 of the transistor Q_{DE11}. The voltage across the capacitor Cₑₙᵥ is the signal S2. The capacitor Cₑₙᵥ terminates the high-frequency components (for example, carrier frequency signal components) of the signal S2 to the reference potential, thereby removing them and allowing only the low-frequency components to pass. As a result, the capacitor Cₑₙᵥ can properly bias the subsequent bias circuits 18 and 19 and transistors (amplifying transistors) to be biased.

The bias circuit 18 includes transistors Q_{DE8}, Q_{DE9}, and Q_{DE10}. The bias circuit 19 (see FIG. 1) has the same circuit configuration as the bias circuit 18, and the description thereof is omitted.

The transistor Q_{DE9} is diode-coupled. The collector and base of the transistor Q_{DE9} are electrically coupled to the one end of the capacitor Cₑₙᵥ. The emitter of the transistor Q_{DE9} is electrically coupled to the collector and base of the transistor Q_{DE8}. The transistor Q_{DE8} is diode-coupled. The emitter of the transistor Q_{DE8} is electrically coupled to the reference potential. A current corresponding to the voltage across the capacitor Cₑₙᵥ flows through the transistors Q_{DE9} and Q_{DE8}.

The collector of the transistor Q_{DE10} is electrically coupled to the power supply potential Vcc. The base of the transistor Q_{DE10} is electrically coupled to the collector and base of the transistor Q_{DE9}. The emitter voltage of the transistor Q_{DE10} is outputted to the peak amplifier 16 (17) as a bias voltage BIAS₁₆ (BIAS₁₇).

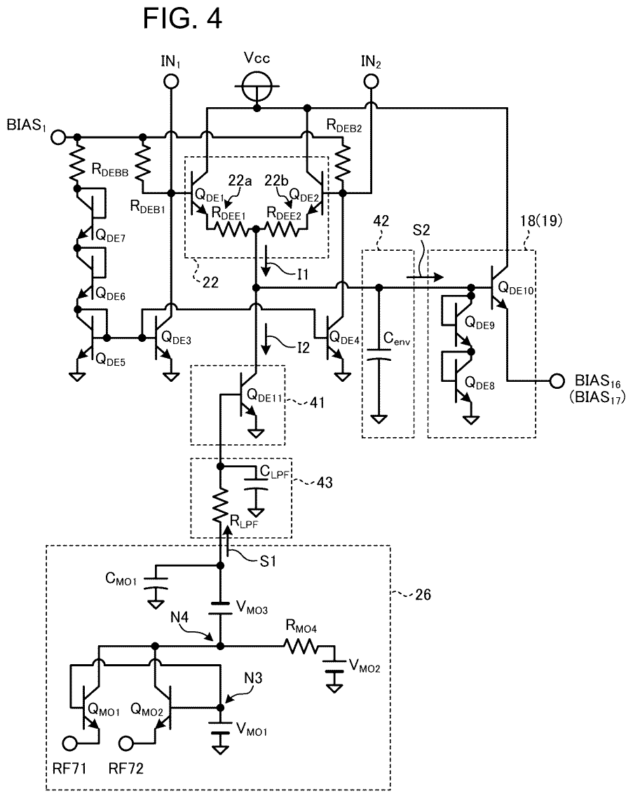

FIG. 4 illustrates an equivalent circuit of the specific example of the detector circuit and the drive-level detector circuit in the power amplifier circuit of the first embodiment.

A constant voltage source V_{MO1} in FIG. 4 corresponds to the resistors R_{MO1}, R_{MO2}, and R_{MO3} and the transistor Q_{MO4} in FIG. 3. A constant voltage source V_{MO2} in FIG. 4 corresponds to the resistor R_{MO5} and the transistors Q_{MO6} and Q_{MO7} in FIG. 3. A constant voltage source V_{MO3} in FIG. 4 corresponds to the transistor Q_{MO5} in FIG. 3.

### (Operation of Drive-Level Detector Circuit)

The operation of the drive-level detector circuit 26 will be described with reference to the equivalent circuit in FIG. 4.

Generally, the output terminal voltage of the final-stage carrier amplifier oscillates around the bias voltage with the voltage amplitude of the high-frequency signal. When the final-stage carrier amplifier saturates, a situation occurs in which the voltage amplitude of the high-frequency signal increases and becomes nearly equal to the bias voltage. In such a situation, there is a moment during the oscillation period of the high-frequency signal when the output terminal voltage approaches 0 V. During this moment, no amplification is achieved, which leads to the phenomenon of amplifier saturation.

The circuit of the first embodiment uses this saturation principle and detects the drive level of the carrier amplifier 13.

Specifically, during the period of the high-frequency signals RF71 and RF72, the transistors Q_{MO1} and Q_{MO2} turn on only during the period when the voltages of the high-frequency signals RF71 and RF72 fall below the voltage of the constant voltage source V_{MO1} minus a voltage drop corresponding to the threshold voltages of the transistors Q_{MO1} and Q_{MO2}.

When the carrier amplifier 13 is operating well below saturation, there is no period during which the transistors Q_{MO1} and Q_{MO2} are on, and no collector current flows through the transistors Q_{MO1} and Q_{MO2}. Therefore, no current flows through the resistor R_{MO4}, and the resistor R_{MO4} does not cause a voltage drop. As a result, the voltage of the signal S1 is equal to the voltage of the constant voltage source V_{MO2} minus the voltage of the constant voltage source V_{MO3}.

When the amplitudes of the high-frequency signals RF71 and RF72 are large, there is a period during which the transistors Q_{MO1} and Q_{MO2} are on, and collector current flows. As a result, current flows through the resistor R_{MO4}, and the resistor R_{MO4} causes a voltage drop.

As the amplitudes of the high-frequency signals RF71 and RF72 become larger, the transistors Q_{MO1} and Q_{MO2} remain on for a longer period, thereby increasing the collector current. As a result, more current flows through the resistor R_{MO4}, and the resistor R_{MO4} causes a larger voltage drop.

Therefore, as the drive level of the carrier amplifier 13 increases, the voltage of the signal S1 becomes equal to the voltage observed when the high-frequency signals RF71 and RF72 are small signals, minus the voltage drop across the resistor R_{MO4}.

Next, the operation of the detector circuit 22 will be described.

When the high-frequency signal IN₁ is greater than or equal to the threshold voltage of the transistor Q_{DE1}, the transistor Q_{DE1} turns on and outputs emitter current. When the high-frequency signal IN₂ is greater than or equal to the threshold voltage of the transistor Q_{DE2}, the transistor Q_{DE2} turns on and outputs emitter current.

That is, as the amplitudes of the high-frequency signals IN₁ and IN₂ increase, (as the power of the high-frequency signal RFin increases), the output current of the detector circuit 22 increases. As the amplitudes of the high-frequency signals IN₁ and IN₂ decrease, (as the power of the high-frequency signal RFin decreases), the output current of the detector circuit 22 decreases.

On the other hand, as described above, the voltage of the signal S1 is relatively low when the drive level of the carrier amplifier 13 is relatively high (when close to saturation) and is relatively high when the drive level of the carrier amplifier 13 is relatively low (when the amplification ratio is reduced).

That is, the relatively higher (the closer to the saturation) the drive level of the carrier amplifier 13, the smaller the collector current I2 of the transistor Q_{DE11}. The relatively lower the drive level of the carrier amplifier 13 (the lower the amplification ratio), the larger the collector current I2 of the transistor Q_{DE11}.

In summary, the voltage across the capacitor Cₑₙᵥ tends to increase as the drive level of the carrier amplifier 13 becomes relatively higher (closer to saturation). Conversely, the voltage across the capacitor Cₑₙᵥ is less likely to increase as the drive level of the carrier amplifier 13 becomes relatively lower (the amplification ratio becomes lower). Furthermore, the voltage across the capacitor Cₑₙᵥ tends to increase as the power of the high-frequency signal RFin becomes higher. The voltage across the capacitor Cₑₙᵥ is less likely to increase as the power of the high-frequency signal RFin becomes lower.

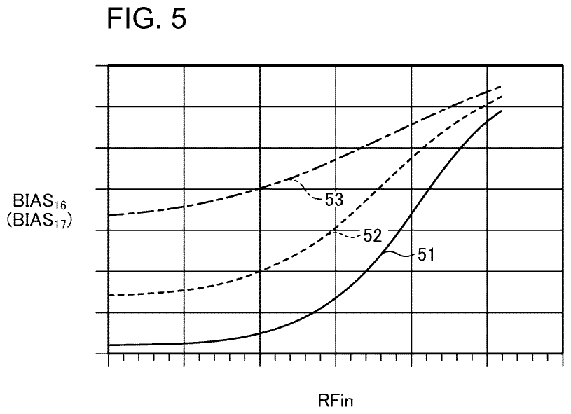

FIG. 5 illustrates an example of the relationship between high-frequency signal power of the power amplifier circuit in the first embodiment and bias voltage applied to the peak amplifier. In FIG. 5, the horizontal axis represents the power of the high-frequency signal RFin, and the vertical axis represents the bias voltage BIAS₁₆ (BIAS₁₇) applied to the peak amplifier 16 (17) by the bias circuit 18 (19).

A waveform 51 represents variation in the bias voltage BIAS₁₆ (BIAS₁₇) when the drive level of the carrier amplifier 13 is relatively low. A waveform 52 represents variation in the bias voltage BIAS₁₆ (BIAS₁₇) when the drive level of the carrier amplifier 13 is relatively intermediate. A waveform 53 represents the variation in the bias voltage BIAS₁₆ (BIAS₁₇) when the drive level of the carrier amplifier 13 is relatively high.

In the case where the drive level of the carrier amplifier 13 is relatively high, as represented by the waveform 53, the detector circuit 22 can activate the peak amplifiers 16 and 17 even if the power of the high-frequency signal RFin is low. In the case where the drive level of the carrier amplifier 13 is relatively low, as represented by the waveform 51, the detector circuit 22 can delay the activation of the peak amplifiers 16 and 17 until the power of the high-frequency signal RFin becomes high.

Therefore, in the case where the drive level of the carrier amplifier 13 is relatively high (close to saturation), the current of the constant-current circuit 41 needs to be reduced so that the peak amplifiers 16 and 17 can be activated even if the power of the high-frequency signal RFin is low. Conversely, in the case where the drive level of the carrier amplifier 13 is relatively low, the current of the constant-current circuit 41 needs to be increased because the peak amplifiers 16 and 17 do not need to be activated until the power of the high-frequency signal RFin becomes high. That is, the configuration in which a voltage BIAS₂ applied to the constant-current circuit 41 changes complementarily to the drive level of the carrier amplifier 13 enables the intended operation of the overall circuit.

The response of the detector circuit 22 becomes faster for the following reason.

First, the first emitter-follower circuit 22a and the second emitter-follower circuit 22b operate differentially. Therefore, the capacitance of the capacitor Cₑₙᵥ can be made smaller than in the configuration where an emitter-follower circuit operates in single-ended mode. The delay in the capacitor Cₑₙᵥ can thereby be reduced, and the change in the signal S2 can be accelerated. That is, the response of the detector circuit 22 becomes faster.

Second, an emitter-follower circuit is able to output large current. Therefore, each of the first emitter-follower circuit 22a and the second emitter-follower circuit 22b can output large current. That is, the output current I1 of the detector circuit 22 can be large. The detector circuit 22 can thereby quickly charge the capacitor Cₑₙᵥ. This means that the rising response of the detector circuit 22 becomes faster.

Third, the transistor Q_{DE11} can discharge the capacitor Cₑₙᵥ by means of a constant current (the collector current I2). Therefore, the transistor Q_{DE11} can quickly discharge the capacitor Cₑₙᵥ. That is, the falling response of the detector circuit 22 becomes faster.

FIG. 6 is a plan view of the power amplification device according to the first embodiment. As illustrated in FIG. 6, the power amplification device 1 is a module including an integrated circuit 4 and the coupler 20, which are provided on the major surface of a substrate 3. The substrate 3 is a substrate made of an insulator and is, for example, a printed wiring board (PWB). The coupler 20 is provided on the major surface of the substrate 3 in the example in FIG. 6, but is not limited thereto, and may be provided in the integrated circuit 4, or does not need to be provided on the major surface of the substrate 3. In the following description, the direction perpendicular to the substrate major surface of the substrate 3 is referred to as a Z direction; a direction vertical to the Z direction is referred to as an X direction; and the direction vertical to the Z direction and the X direction is referred to as a Y direction. In the example described below, the signal S2 outputted from the control circuit 21 is supplied to only the bias circuit 18.

The substrate of the integrated circuit 4 is a semiconductor substrate containing, for example, a compound semiconductor. Examples of the compound semiconductor include gallium arsenide (GaAs), gallium phosphide (GaP), gallium nitride (GaN), and indium phosphide (InP). The integrated circuit 4 is provided on the major surface of the substrate 3. The integrated circuit 4 includes the splitter 11, the carrier amplifiers 12 and 13, the peak amplifiers 16 and 17, and the bias circuits 14, 15, 18, and 19, the drive-level detector circuit 26, and the control circuit 21. The material of the integrated circuit 4 is not limited to the above-described substrate and may be a substrate containing doped silicon. The locations where the bias circuits 14, 15, 18, and 19 are provided are merely examples and are not limited to those in the example in FIG. 6, as long as they are included in the integrated circuit 4.

In the following description, a placement region where an element is arranged refers to a region of the integrated circuit 4 occupied by the components of the element. For example, the placement region where the carrier amplifier 13 is arranged refers to a placement region A13.

In the first embodiment, the carrier amplifiers 12 and 13 are arranged in the X direction. The peak amplifiers 16 and 17 are arranged in the X direction. The carrier amplifiers 12 and 13 are adjacent to the peak amplifiers 16 and 17 in the Y direction, respectively.

In the example in FIG. 6, a matching circuit 24 is provided between a placement region A12, where the carrier amplifier 12 is arranged, and the placement region A13, where the carrier amplifier 13 is arranged. The matching circuit 24 matches its input impedance to that of the carrier amplifier 13. A matching circuit 25 is provided between a placement region A16, where the peak amplifier 16 is arranged, and a placement region A17, where the peak amplifier 17 is arranged. The matching circuit 25 matches its input impedance to that of the peak amplifier 17. The matching circuits 24 and 25 are not essential components.

In plan view in the Z direction, the placement region of the drive-level detector circuit 26 is adjacent to the placement region A13, where the amplifier of the carrier amplifier 13 is arranged. The placement region of the drive-level detector circuit 26 can be considered adjacent to the placement region A13, where the amplifier of the carrier amplifier 13 is arranged, if the distance between the placement region of the drive-level detector circuit 26 and the placement region A13, where the amplifier of the carrier amplifier 13 is arranged, is less than the distance between the placement region of the drive-level detector circuit 26 and the placement region A12, where the amplifier of the carrier amplifier 12 is arranged. Here, the distance between placement regions refers to the shortest distance from the boundary of one of the placement regions to the boundary of the other placement region in plan view in the Z direction.

In the first embodiment, the placement region where the drive-level detector circuit 26 is arranged is located between the placement region A13, where the carrier amplifier 13 is arranged, and the placement region A17, where the peak amplifier 17 is arranged. This can reduce the wiring length from the carrier amplifier 13 to the drive-level detector circuit 26, thereby improving the accuracy of detecting instantaneous variations in the output of the carrier amplifier 13.

The control circuit 21 is provided between the placement region A12, where the carrier amplifier 12 is arranged, and the placement region A16, where the peak amplifier 16 is arranged. This can reduce the wiring length from the drive-level detector circuit 26 to the control circuit 21, thereby suppressing the influence of noise from peripheral circuits on the signal S1.

As described above, the power amplification device 1 according to the first embodiment includes: the substrate 3; the integrated circuit 4, which is provided on the major substrate surface; the splitter 11; the carrier amplifiers 12 and 13, which amplify the inputted high-frequency signal RF2; the peak amplifiers 16 and 17, which amplify the inputted high-frequency signal RF5; the first bias circuit (the bias circuits 14 and 15) that provides bias to the carrier amplifiers 12 and 13; the second bias circuit (the bias circuits 18 and 19) that provides bias to the peak amplifiers 16 and 17; the drive-level detector circuit 26, which outputs the signal indicating the drive level of the carrier amplifier 13, based on the high-frequency signal RF4 outputted by the carrier amplifier 13; the detector circuit 22, which outputs the control signal (the signal S2) to control the second bias circuit, based on the inputted high-frequency signal RF2 and the signal S1 indicating the drive level of the carrier amplifier 13; and the coupler 20, which is provided on the major surface of the substrate 3. The detector circuit 22 varies the threshold for the control signal based on the inputted high-frequency signal RF2 and the signal S1 indicating the drive level of the carrier amplifier 13. The integrated circuit 4 includes the splitter 11, the carrier amplifiers 12 and 13, the peak amplifiers 16 and 17, the first bias circuit, the second bias circuit, the drive-level detector circuit 26, and the detector circuit 22, which are provided at different positions when viewed in the direction perpendicular to the major surface of the substrate 3. When viewed in the direction perpendicular to the major surface of the substrate, the placement region of the drive-level detector circuit 26 is adjacent to the placement regions A12 and A13, where the amplifiers of the carrier amplifiers 12 and 13 are arranged.

As a result, the wiring length from the final-stage carrier amplifier 13 to the drive-level detector circuit 26 can be reduced. This can improve the accuracy of detecting instantaneous variations in the output of the final-stage carrier amplifier 13, thereby suppressing the degradation in the quality of high-frequency output signals.

The detector circuit 22 may receive the high-frequency signal RFin or RF1 inputted from the outside or the high-frequency signal RF2 inputted to the carrier amplifier. In this case as well, the degradation in the quality of high-frequency output signals can be suppressed.

As a desired aspect, the carrier amplifiers 12 and 13 include the first-stage carrier amplifier 12, which amplifies the inputted high-frequency signal RF2, and the final-stage carrier amplifier 13, which amplifies the high-frequency signal RF3 outputted from the first-stage carrier amplifier 12. The peak amplifiers 16 and 17 include the first-stage peak amplifier 16, which amplifies the inputted high-frequency signal RF5, and the final-stage peak amplifier 17, which amplifies the high-frequency signal RF6 outputted from the first-stage peak amplifier 16. When viewed in the direction perpendicular to the major surface of the substrate 3, the placement region of the drive-level detector circuit 26 is adjacent to the placement region A13, where the amplifier of the final-stage carrier amplifier 13 is arranged. In this case as well, the degradation in the quality of high-frequency output signals can be suppressed.

As a desired aspect, when viewed in the direction perpendicular to the major surface of the substrate 3, the placement region of the drive-level detector circuit 26 is located between the placement region A13, where the amplifier of the final-stage carrier amplifier 13 is arranged, and the placement region A17, where the amplifier of the final-stage peak amplifier 17 is arranged. This can further reduce the wiring length from the final-stage carrier amplifier 13 to the drive-level detector circuit 26, thereby further suppressing the degradation in the quality of high-frequency output signals.

As a desired aspect, when viewed in the direction perpendicular to the major surface of the substrate 3, the placement region of the detector circuit 22 is located between the placement region A12, where the amplifier of the first-stage carrier amplifier 12 is arranged, and the placement region A16, where the amplifier of the first-stage peak amplifier 16 is arranged. This can reduce the wiring length from the drive-level detector circuit 26 to the detector circuit 22, thereby suppressing the influence of noise from peripheral circuits on the signal S1. As a result, the degradation in the quality of high-frequency output signals can be further suppressed.

### Second Embodiment

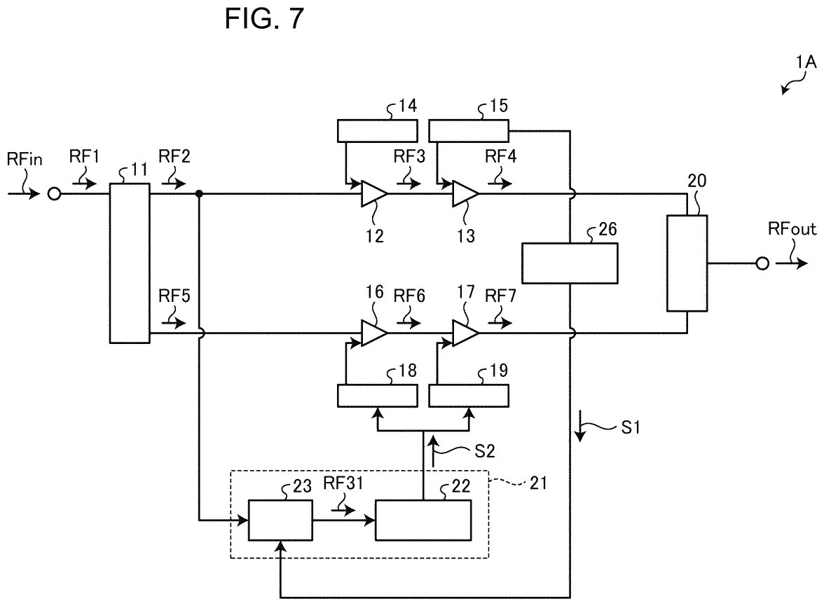

FIG. 7 illustrates a circuit configuration of a power amplification device according to a second embodiment. As illustrated in FIG. 7, the second embodiment differs from the first embodiment in that the drive-level detector circuit 26 outputs the signal S1 based on a high-frequency signal outputted by the bias circuit 15.

In a power amplification device 1A according to the second embodiment, the control circuit 21 further includes a variable attenuator 23 compared to the power amplification device 1 (see FIG. 1) according to the first embodiment.

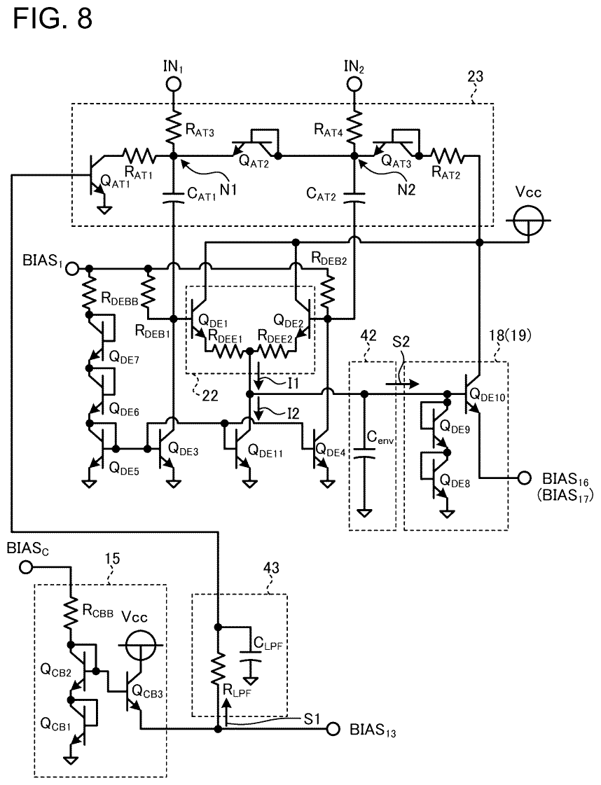

The variable attenuator 23 receives the high-frequency signal RFin and the signal S1, which indicates the drive level of the carrier amplifier 13. The variable attenuator 23 may receive the high-frequency signal RF1 or RF2 instead of the high-frequency signal RFin. FIG. 7 and the later-described plan view of the power amplification device 1A illustrate an example in which the high-frequency signal RF2 is inputted to the detector circuit 22 (see FIG. 8).

The variable attenuator 23 attenuates the high-frequency signal RFin based on the signal S1 and outputs the resulting signal as a high-frequency signal RF31 to the detector circuit 22. The detector circuit 22 outputs the signal S2 to the bias circuits 18 and 19 based on the high-frequency signal RF31.

In the second embodiment, the bias point of the detector circuit 22 is fixed. The amount of attenuation of the variable attenuator 23, which is provided upstream of the detector circuit 22, is changed based on the signal S1. The control circuit 21A can thereby output the signal S2 based on the drive level of the carrier amplifier 13.

FIG. 8 illustrates a specific example of the detector circuit and the variable attenuator in the power amplifier circuit according to the second embodiment. The base of the transistor Q_{DE11} is electrically coupled to the collector and base of the transistor Q_{DE5}. In the second embodiment, therefore, the collector current I2 is fixed.

The variable attenuator 23 includes resistors R_{AT1}, R_{AT2}, R_{AT3}, and R_{AT4} and transistors Q_{AT1}, Q_{AT2}, Q_{AT3}, and capacitors C_{AT1} and C_{AT2}.

One end of the resistor R_{AT2} is electrically coupled to the power supply potential Vcc. The other end of the resistor R_{AT2} is electrically coupled to the collector and base of the transistor Q_{AT3}. That is, the transistor Q_{AT3} is diode-coupled. The emitter of the transistor Q_{AT3} is electrically coupled to a node N2.

The collector and base of the transistor Q_{AT2} are electrically coupled to the node N2. That is, the transistor Q_{AT2} is diode-coupled. The emitter of the transistor Q_{AT2} is electrically coupled to a node N1.

One end of the resistor R_{AT1} is electrically coupled to the node N1. The other end of the resistor R_{AT1} is electrically coupled to the collector of the transistor Q_{AT1}. The emitter of the transistor Q_{AT1} is electrically coupled to the reference potential. The base of the transistor Q_{AT1} receives the signal S1 that has been low-pass filtered by the low pass filter 43.

One end of the resistor R_{AT3} receives the high-frequency signal IN₁. The other end of the resistor R_{AT3} is electrically coupled to the node N1. One end of the capacitor C_{AT1} is electrically coupled to the node N1. The other end of the capacitor C_{AT1} is electrically coupled to the base of the transistor Q_{DE1}.

One end of the resistor R_{AT4} receives the high-frequency signal IN₂. The other end of the resistor R_{AT4} is electrically coupled to the node N2. One end of the capacitor C_{AT2} is electrically coupled to the node N2. The other end of the capacitor C_{AT2} is electrically coupled to the base of the transistor Q_{DE2}.

The variable attenuator 23 is an attenuator operating based on the principle that the equivalent resistance of the transistor Q_{AT1} decreases as the current flowing through the transistor Q_{AT1} increases.

When the drive level of the carrier amplifier 13 is relatively low, a relatively high voltage is applied to the base of the transistor Q_{AT1}, which serves as a control terminal of the variable attenuator 23. In this process, a large collector current flows through the transistor Q_{AT1}, and a large current also flows through the transistors Q_{AT2} and Q_{AT3}. Therefore, the equivalent resistances of the transistors Q_{AT1}, Q_{AT2}, and Q_{AT3} are reduced, and the nodes N1 and N2, to which the high-frequency signals IN₁ and IN₂ are transmitted, are nearly short circuited. As a result, the variable attenuator 23 does not allow the high-frequency signals IN₁ and IN₂ to pass.

On the other hand, when the drive level of the carrier amplifier 13 is relatively high, no current flows through the transistors Q_{AT1}, Q_{AT2}, and Q_{AT3}. As a result, the variable attenuator 23 allows the high-frequency signals IN₁ and IN₂ to pass.

Since the detector circuit 22 is provided downstream of the variable attenuator 23, the detector circuit 22 can output the signal S2 based on the drive level of the carrier amplifier 13.

The variable attenuator 23 substantially only needs to have controllable bandpass characteristics (attenuation characteristics) and ensure minimal delay in the input/output characteristics of the high-frequency signals IN₁ and IN₂. Therefore, the variable attenuator 23 can be implemented using various configurations, such as a variable gain amplifier.

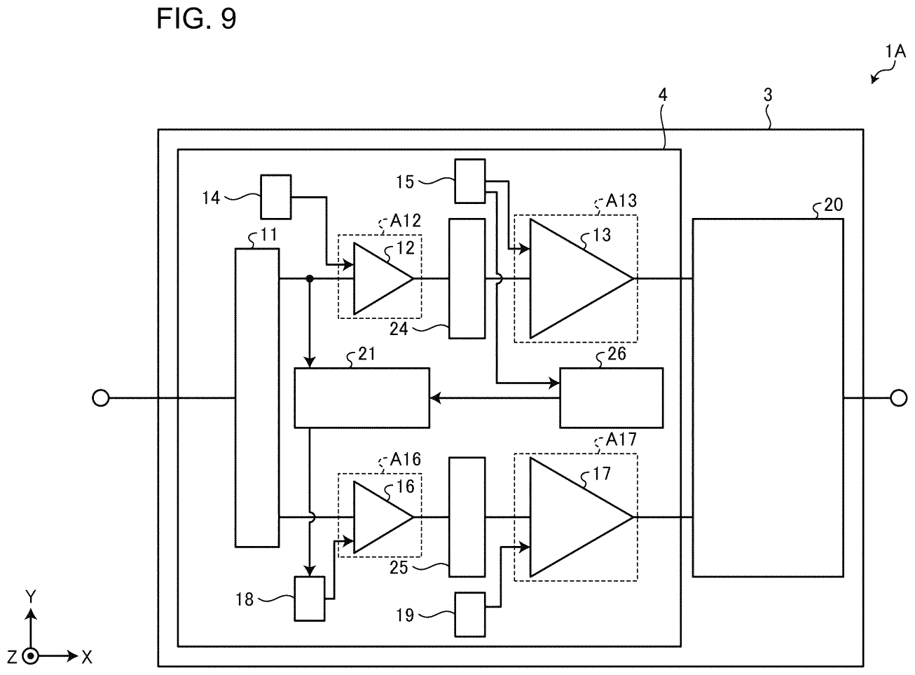

FIG. 9 is a plan view of the power amplification device according to the second embodiment. As illustrated in FIG. 9, in the second embodiment, the drive-level detector circuit 26 is coupled to the bias circuit 15. In the example of FIG. 9, the signal S2 outputted from the control circuit 21 is supplied to only the bias circuit 18.

As described above, the power amplification device 1A according to the second embodiment includes: the substrate 3; the integrated circuit 4, which is provided on the major surface of the substrate 3; the splitter 11; the carrier amplifiers 12 and 13, which amplify the inputted high-frequency signal RF2; the peak amplifiers 16 and 17, which amplify the inputted high-frequency signal RF5; the first bias circuit (the bias circuits 14 and 15) that provides bias to the carrier amplifiers 12 and 13; the second bias circuit (the bias circuits 18 and 19) that provides bias to the peak amplifiers 16 and 17; the drive-level detector circuit 26, which outputs the signal S1 indicating the drive level of the carrier amplifier 13, based on the high-frequency signal outputted by the first bias circuit (the bias circuit 15); the control circuit 21; and the coupler 20, which is provided on the major surface of the substrate 3. The integrated circuit 4 includes the splitter 11, the carrier amplifiers 12 and 13, the peak amplifiers 16 and 17, the first bias circuit, the second bias circuit, the drive-level detector circuit 26, and the control circuit 21, which are provided at different positions when viewed in the direction perpendicular to the major surface of the substrate 3. The control circuit 21 includes: the detector circuit 22, which outputs the control signal (the signal S2) to control the second bias circuit; and a variable attenuator 23, which outputs to the detector circuit 22 based on the high-frequency signal RF2 inputted to the carrier amplifier and the signal S1 indicating the drive level of the carrier amplifier, the high-frequency signal RF31, which is obtained by attenuating the inputted high-frequency signal RF2. When viewed in the direction perpendicular to the major surface of the substrate 3, the placement region of the drive-level detector circuit 26 is adjacent to the placement region A13, where the amplifier of the carrier amplifier 13 is arranged.

As a result, the wiring length from the first bias circuit to the drive-level detector circuit can be reduced. This can improve the accuracy of detecting instantaneous variations in the output of the first bias circuit, thereby suppressing the degradation in the quality of high-frequency output signals.

### Third Embodiment

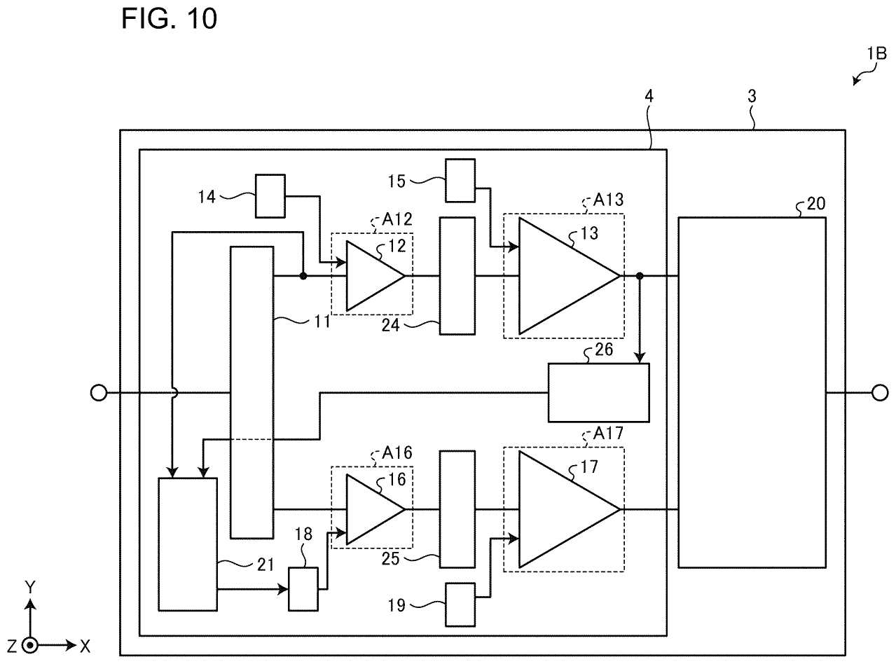

FIG. 10 is a plan view of a power amplification device according to a third embodiment. As illustrated in FIG. 10, the third embodiment differs from the first embodiment in that the control circuit 21 is provided on the other side of the carrier amplifier 12 from the carrier amplifier 13 in the X direction.

In the third embodiment, the distance from the placement region of the control circuit 21 to the placement region A12, where the amplifier of the carrier amplifier 12 is arranged, is less than the distance from the control circuit 21 to the placement region A13, where the amplifier of the carrier amplifier 13 is arranged. In the example in FIG. 10, the control circuit 21 is provided on the opposite side of the splitter 11 from the carrier amplifier 13 in the X-direction. This can reduce the malfunctions of the control circuit 21 caused by the operating temperature of the carrier amplifier 13.

In the third embodiment, the distance from the placement region of the control circuit 21 to the placement region A12, where the amplifier of the carrier amplifier 12 is arranged, is greater than the distance from the control circuit 21 to the placement region A16, where the amplifier of the peak amplifier 16 is arranged. This can further reduce the malfunctions of the control circuit 21 caused by the operating temperature of the carrier amplifier 13. Furthermore, the wiring length from the control circuit 21 to the bias circuit 18 can be reduced, thereby suppressing the influence of noise from peripheral circuits on the signal S2.

As described above, in a power amplification device 1B according to the third embodiment, when viewed in the direction perpendicular to the major surface of the substrate 3, the distance from the placement region of the detector circuit 22 to the placement region A12, where the amplifier of the first-stage carrier amplifier 12 is arranged, is less than the distance from the detector circuit 22 to the placement region A13, where the amplifier of the final-stage carrier amplifier 13 is arranged, and is greater than the distance from the detector circuit 22 to the placement region A12, where the amplifier of the first-stage peak amplifier 16 is arranged. This can reduce the malfunctions of the detector circuit 22 caused by the operating temperature of the final-stage carrier amplifier 13. Furthermore, the reduced wiring length from the detector circuit 22 to the bias circuit can suppress the influence of noise from peripheral circuits on the signal S2. As a result, the degradation in the quality of high-frequency output signals can be further reduced.

### Fourth Embodiment

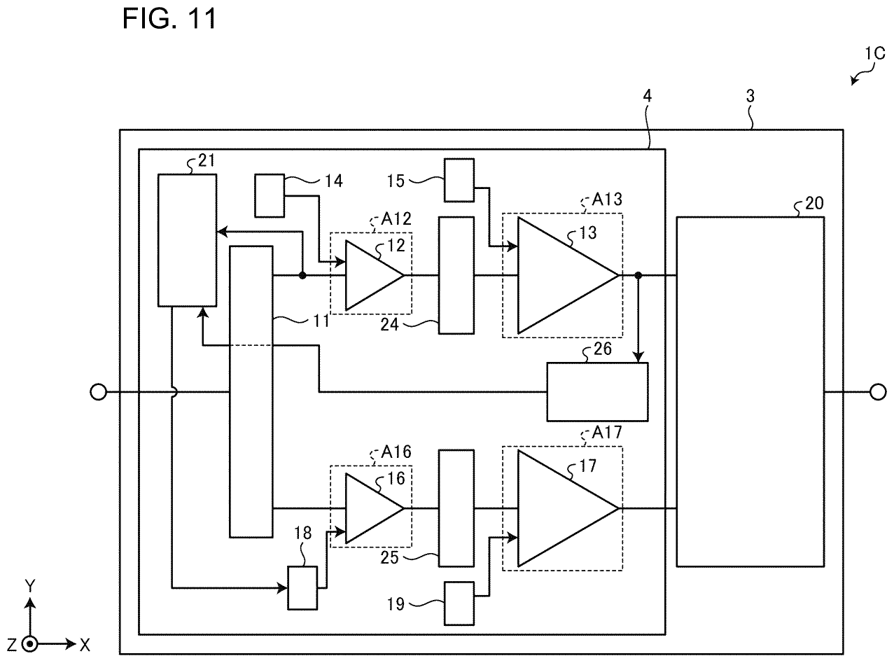

FIG. 11 is a plan view of a power amplification device according to the fourth embodiment. As illustrated in FIG. 11, the fourth embodiment differs from the first embodiment in that the control circuit 21 is provided on the opposite side of the carrier amplifier 12 from the carrier amplifier 13 in the X direction.

In the fourth embodiment, the distance from the placement region of the control circuit 21 to the placement region A12, where the amplifier of the carrier amplifier 12 is arranged, is less than the distance from the control circuit 21 to the placement region A13, where the amplifier of the carrier amplifier 13 is arranged. In the example in FIG. 11, the control circuit 21 is provided on the opposite side of the splitter 11 from the carrier amplifier 13 in the X direction. This can reduce the malfunctions of the control circuit 21 caused by the operating temperature of the carrier amplifier 13.

In the fourth embodiment, the distance from the placement region of the control circuit 21 to the placement region A12, where the amplifier of the carrier amplifier 12 is arranged, is less than the distance from the control circuit 21 to the placement region A16, where the amplifier of the peak amplifier 16 is arranged. This can reduce the wiring length from the input terminal of the carrier amplifier 12 to the control circuit 21, thereby suppressing the influence of noise from peripheral circuits on the high-frequency signal to be inputted to the control circuit 21.

As described above, in a power amplification device 1C according to the fourth embodiment, when viewed in the direction perpendicular to the major surface of the substrate 3, the distance from the placement region of the detector circuit 22 to the placement region A12, where the amplifier of the first-stage carrier amplifier 12 is arranged, is less than the distance from the detector circuit 22 to the placement region A13, where the amplifier of the final-stage carrier amplifier 13 is arranged, and is less than the distance from the detector circuit 22 to the placement region A16, where the amplifier of the first-stage peak amplifier 16 is arranged. This can reduce the malfunctions of the detector circuit 22 caused by the operating temperature of the final-stage carrier amplifier 13. Furthermore, the reduced wiring length from the input terminal of the carrier amplifier 12 to the control circuit 21 can suppress the influence of noise from peripheral circuits on the high-frequency signal to be inputted to the control circuit 21. As a result, the degradation in the quality of high-frequency output signals can be further reduced.

### Fifth Embodiment

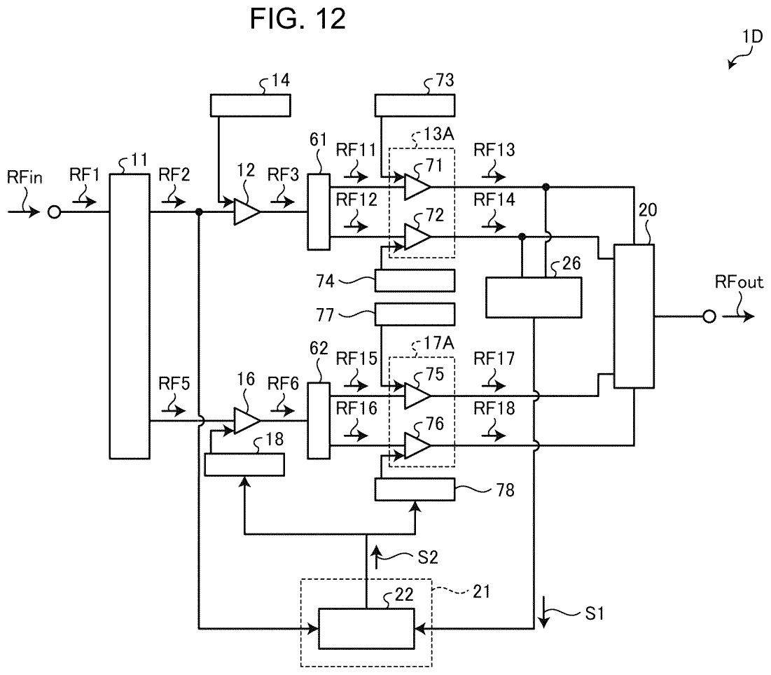

FIG. 12 illustrates a circuit configuration of a power amplification device according to a fifth embodiment. As illustrated in FIG. 12, the fifth embodiment differs from the first embodiment in that a carrier amplifier 13A and a peak amplifier 17A each are a differential amplifier including a plurality of amplifiers. The Doherty amplifier of a power amplification device 1D according to the fifth embodiment includes the splitter 11, the first-stage carrier amplifier 12, the final-stage carrier amplifier 13A, the first-stage peak amplifier 16, the final-stage peak amplifier 17A, dividers 61 and 62, the bias circuits 14 and 18, bias circuits 73, 74, 77, and 78, the coupler 20, the control circuit 21, and the drive-level detector circuit 26.

The bias circuits 14, 73, and 74 are examples of the “first bias circuit” of the present disclosure. The bias circuits 18, 77, and 78 are examples of the “second bias circuit” of the present disclosure.

The divider 61 outputs high-frequency signals RF11 and RF12, which constitute a differential signal, based on the inputted high-frequency signal RF3. For example, the high-frequency signal RF11 is a positive high-frequency signal while the high-frequency signal RF12 is a negative high-frequency signal. The divider 62 outputs high-frequency signals RF15 and RF16, which constitute a differential signal, based on the inputted high-frequency signal RF6. For example, the high-frequency signal RF15 is a positive high-frequency signal while the high-frequency signal RF16 is a negative high-frequency signal. The divider 61 is composed of, for example, a balun or a transformer.

The carrier amplifier 13A and the peak amplifier 17A are differential amplifiers. The carrier amplifier 13A includes a first amplifier 71 and a second amplifier 72. The peak amplifier 17A includes a first amplifier 75 and a second amplifier 76. The first amplifiers 71 and 75 and the second amplifiers 72 and 76 are amplifiers each including a plurality of transistors. The plurality of transistors included in the first amplifiers 71 and 75 and the second amplifiers 72 and 76 are, for example, heterojunction bipolar transistors (HBTs). However, the plurality of transistors are not limited thereto, and may be field-effect transistors (FETs). In the present disclosure, the differences in voltage amplitude between the output signals of the first amplifiers 71 and 75 and the output signals of the second amplifiers 72 and 76 may be less than or equal to 3 dB, and the phase difference ranges from 90° to 270°.

The bias circuit 73 provides bias to the first amplifier 71. The bias circuit 74 provides bias to the second amplifier 72. The first amplifier 71 within the carrier amplifier 13A amplifies the high-frequency signal RF11 and outputs the resulting signal as a high-frequency signal RF13 to the coupler 20. The second amplifier 72 within the carrier amplifier 13A amplifies the high-frequency signal RF12 and outputs the resulting signal as a high-frequency signal RF14 to the coupler 20.

The bias circuit 77 provides bias to the first amplifier 75. The bias circuit 78 provides bias to the second amplifier 76. The first amplifier 75 within the peak amplifier 17A amplifies the high-frequency signal RF15 and outputs the resulting signal as a high-frequency signal RF17 to the coupler 20. The second amplifier 76 within the peak amplifier 17A amplifies the high-frequency signal RF16 and outputs the resulting signal as a high-frequency signal RF18 to the coupler 20.

The coupler 20 couples the high-frequency signals RF13, RF14, RF17, and RF18 to output the high-frequency signal RFout.

The drive-level detector circuit 26 outputs the signal S1 to the detector circuit 22 based on the high-frequency signals RF13 and RF14 outputted by the first amplifier 71 and the second amplifier 72 within the carrier amplifier 13.

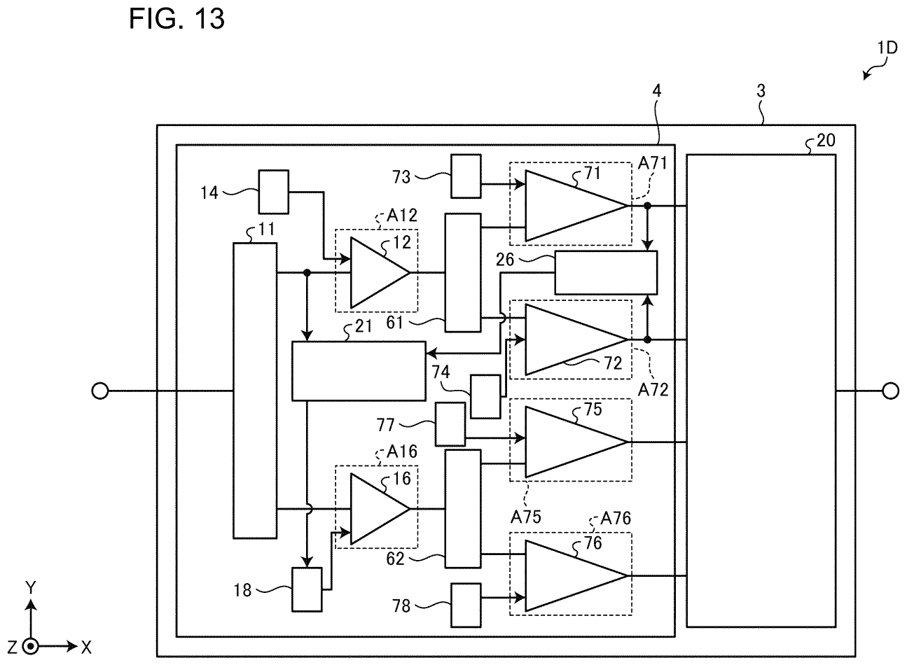

FIG. 13 is a plan view of the power amplification device according to the fifth embodiment. In the fifth embodiment, the integrated circuit 4 includes the dividers 61 and 62, the first amplifiers 71 and 75, the second amplifiers 72 and 76, and the bias circuits 73, 74, 77, and 78. In the integrated circuit 4, the locations where the bias circuits 73, 74, 77, and 78 are provided are merely examples and are not limited to those in the example in FIG. 13, as long as they are included in the integrated circuit 4.

In the fifth embodiment, the second amplifiers 72 and 76 are, respectively, located in the Y direction with respect to the first amplifiers 71 and 75 in the integrated circuit 4. That is, the first amplifier 71, the second amplifier 72, the first amplifier 75, and the second amplifier 76 are arranged in the Y direction in this order.

In the fifth embodiment, as illustrated in FIG. 13, the carrier amplifier is a differential amplifier including the first amplifier 71 and the second amplifier 72. The placement region of the drive-level detector circuit 26 is located between the placement region A71, where the first amplifier 71 is arranged, and the placement region A72, where the second amplifier is arranged. This can reduce the wiring lengths from the first and second amplifiers 71 and 72 to the drive-level detector circuit 26, thereby improving the accuracy of detecting instantaneous variations in the output of the carrier amplifier 13A.

In the example in FIG. 13, as in the first embodiment, the placement region where the control circuit 21 is arranged is located between the placement region A12, where the carrier amplifier 12 is arranged, and the placement region A16, where the peak amplifier 16 is arranged. This can reduce the wiring length from the drive-level detector circuit 26 to the control circuit 21, thereby suppressing the influence of noise from peripheral circuits on the signal S1. The control circuit 21 may be provided at the position according to the third or fourth embodiment.

As described above, in a power amplification device 1D according to the fifth embodiment, the final-stage carrier amplifier is a differential amplifier including the first amplifier 71 and the second amplifier 72, and the placement region of the drive-level detector circuit 26 is located between the placement region where the first amplifier 71 is arranged and the placement region where the second amplifier 72 is arranged. This can reduce the wiring lengths from the first amplifier 71 and the second amplifier 72 within the final-stage carrier amplifier to the drive-level detector circuit 26, thereby improving the accuracy of detecting instantaneous variations in the output of the final-stage carrier amplifier. As a result, the degradation in the quality of high-frequency output signals can be suppressed.

### Sixth Embodiment

In a power amplification device according to a sixth embodiment, the control circuit is coupled to the peak amplifier.

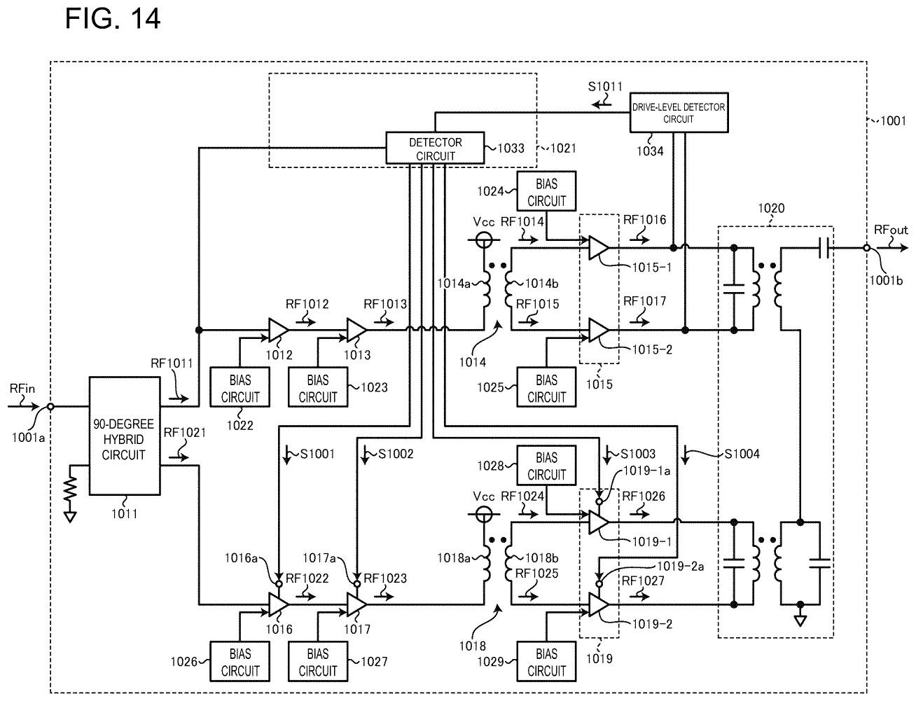

FIG. 14 illustrates a circuit configuration of a power amplification device according to the sixth embodiment. A Doherty amplifier 1001 included in the power amplification device according to the sixth embodiment amplifies the high-frequency signal RFin inputted to an input terminal 1001a and outputs the high-frequency signal RFout from the output terminal 1001b.

The Doherty amplifier 1001 includes a splitter 1011, a first-stage (driver-stage) carrier amplifier 1012, a middle-stage carrier amplifier 1013, a balun 1014, a final-stage (power-stage) carrier amplifier 1015, a first-stage peak amplifier 1016, a middle-stage peak amplifier 1017, a balun 1018, a final-stage peak amplifier 1019, a coupler 1020, a control circuit 1021, a drive-level detector circuit 1034, and bias circuits 1022 to 1029. The control circuit 1021 includes a detector circuit 1033. The Doherty amplifier 1001 includes three stages, but the present disclosure is not limited thereto. The number of stages of the Doherty amplifier 1001 may be one, two, or four or more. The bias circuits 1022 to 1025 are examples of the “first bias circuit” of the present disclosure. The bias circuits 1026 to 1029 are examples of the “second bias circuit” of the present disclosure.

The splitter 1011 is a 90-degree hybrid circuit. The 90-degree hybrid circuit splits the high-frequency signal RFin inputted to the input terminal 1001a into high-frequency signals RF1011 and RF1021, which differ in phase by substantially 90°. The 90-degree hybrid circuit then outputs the high-frequency signal RF1011 to the carrier amplifiers 1012 and a detector circuit 1033 and outputs the high-frequency signal RF1021 to the peak amplifier 1016. The term “substantially 90°” includes not only a phase difference of 90° but also phase differences ranging from 45° to 135°.

The phase of the high-frequency signal RF1021 is exemplified as lagging behind that of the high-frequency signal RF1011 by 90°. The power of the high-frequency signal RF1021 is exemplified as being equal to that of the high-frequency signal RF1011.

The bias circuit 1022 provides bias to the carrier amplifier 1012. The carrier amplifier 1012 amplifies the high-frequency signal RF1011 and outputs the resulting signal as a high-frequency signal RF1012 to the carrier amplifier 1013. The bias circuit 1023 provides bias to the carrier amplifier 1013. The carrier amplifier 1013 amplifies the high-frequency signal RF1012 and outputs the resulting signal as a high-frequency signal RF1013 to one end of a first winding 1014a of the balun 1014.

The other end of the first winding 1014a of the balun 1014 is electrically coupled to the power supply potential Vcc. The balun 1014 transforms the high-frequency signal RF1013 into high-frequency signals RF1014 and RF1015, which constitute a differential signal, and outputs the high-frequency signals RF1014 and RF1015 from the respective ends of a second winding 1014b.

The bias circuit 1024 provides bias to a carrier amplifier 1015-1. The carrier amplifier 1015-1 amplifies the high-frequency signal RF1014 and outputs the resulting signal as a high-frequency signal RF1016 to the coupler 1020. The bias circuit 1025 provides bias to a carrier amplifier 1015-2. The carrier amplifier 1015-2 amplifies the high-frequency signal RF1015 and outputs the resulting signal as a high-frequency signal RF1017 to the coupler 1020.

The bias circuit 1026 provides bias to the peak amplifier 1016. The peak amplifier 1016 includes an enable terminal 1016a, which is used to control an operating state (a high-frequency signal amplified state) and a non-operating state (a high-frequency signal non-amplified state). The enable terminal 1016a receives a control signal S1001 from the detector circuit 1033. The peak amplifier 1016 is switched to the operating state or the non-operating state depending on the control signal S1001. The control signal S1001 may be a voltage signal or a current signal. In the operating state, the peak amplifier 1016 amplifies the high-frequency signal RF1021 and outputs the resulting signal as a high-frequency signal RF1022 to the peak amplifier 1017. In the non-operating state, the peak amplifier 1016 does not amplify the high-frequency signal RF1021.

One end of a first winding 1018a of the balun 1018 is electrically coupled to the power supply potential Vcc. The balun 1018 transforms the high-frequency signal RF1023 into high-frequency signals RF1024 and RF1025, which constitute a differential signal, and outputs the high-frequency signals RF1024 and RF1025 from the respective ends of a second winding 1018b.

The bias circuit 1027 provides bias to the peak amplifier 1017. The peak amplifier 1017 includes an enable terminal 1017a, which is used to control the operating state and the non-operating state. The enable terminal 1017a receives a control signal S1002 from the detector circuit 1033. The peak amplifier 1017 is switched to the operating state or the non-operating state depending on the control signal S1002. The control signal S1002 may be a voltage signal or a current signal. In the operating state, the peak amplifier 1017 amplifies the high-frequency signal RF1022 and outputs the resulting signal as a high-frequency signal RF1023 to the other end of the first winding 1018a of the balun 1018. In the non-operating state, the peak amplifier 1017 does not amplify the high-frequency signal RF1022.

The bias circuit 1028 provides bias to a peak amplifier 1019-1. The peak amplifier 1019-1 includes an enable terminal 1019-1a, which is used to control the operating state and the non-operating state. The enable terminal 1019-1a receives a control signal S1003 from the detector circuit 1033. The peak amplifier 1019-1 is switched to the operating state or the non-operating state depending on the control signal S1003. The control signal S1003 may be a voltage signal or a current signal. In the operating state, the peak amplifier 1019-1 amplifies the high-frequency signal RF1024 and outputs the resulting signal as a high-frequency signal RF1026 to the coupler 1020. In the non-operating state, the peak amplifier 1019-1 does not amplify the high-frequency signal RF1024.

The bias circuit 1029 provides bias to a peak amplifier 1019-2. The peak amplifier 1019-2 includes an enable terminal 1019-2a, which is used to control the operating state and the non-operating state. The enable terminal 1019-2a receives a control signal S1004 from the detector circuit 1033. The peak amplifier 1019-2 is switched to the operating state or the non-operating state depending on the control signal S1004. The control signal S1004 may be a voltage signal or a current signal. In the operating state, the peak amplifier 1019-2 amplifies the high-frequency signal RF1025 and outputs the resulting signal as a high-frequency signal RF1027 to the coupler 1020. In the non-operating state, the peak amplifier 1019-2 does not amplify the high-frequency signal RF1025.

In the sixth embodiment, the carrier amplifier 1015 is a differential amplifier including the carrier amplifier 1015-1 for the first phase and the carrier amplifier 1015-2 for the second phase. In the sixth embodiment, the peak amplifier 1019 is a differential amplifier including the peak amplifier 1019-1 for the first phase and the peak amplifier 1019-2 for the second phase. In the sixth embodiment, the difference in voltage amplitude between output signals of one amplifier within the differential amplifier and the other amplifier may be less than or equal to 3 dB, and the phase difference ranges from 90° to 270°.

In the sixth embodiment, each of the carrier amplifiers 1012 and 1013 is a single-ended amplifier, but the present disclosure is not limited thereto. The carrier amplifiers 1012 and 1013 may each be a differential amplifier. In the sixth embodiment, each of the peak amplifiers 1016 and 1017 is a single-ended amplifier, but the present disclosure is not limited thereto. The peak amplifiers 1016 and 1017 may each be a differential amplifier.

In the sixth embodiment, the carrier amplifier 1015 is a differential amplifier, but the present disclosure is not limited thereto. The carrier amplifier 1015 may be a single-ended amplifier. In the sixth embodiment, the peak amplifier 1019 is a differential amplifier, but the present disclosure is not limited thereto. The peak amplifier 1019 may be a single-ended amplifier.

When the peak amplifiers 1016, 1017, 1019-1, and 1019-2 are in the non-operating state, the coupler 1020 couples the high-frequency signals RF1016 and RF1017 to output the high-frequency signal RFout. When the peak amplifiers 1016, 1017, 1019-1, and 1019-2 are in the operating state, the coupler 1020 couples the high-frequency signals RF1016, RF1017, RF1026, and RF1027 to output the high-frequency signal RFout.

The drive-level detector circuit 1034 detects the drive level (operating level) of the carrier amplifier 1015 based on the high-frequency signals RF1016 and RF1017 and outputs a detection signal S1011, which indicates the drive level of the carrier amplifier 1015, to the detector circuit 1033. The detection signal S1011 may be a signal (an inverted signal) that changes complementarily to the drive level of the carrier amplifier 1015.

The detector circuit 1033 outputs the control signals S1001, S1002, S1003, and S1004 respectively to the peak amplifiers 1016, 1017, 1019-1, and 1019-2 based on the high-frequency signal RF1011. For example, the detector circuit 1033 is exemplified as outputting the control signals S1001, S1002, S1003, and S1004 to switch the peak amplifiers 1016, 1017, 1019-1, and 1019-2 to the operating state when the amplitude of the high-frequency signal RF1011 is large. For example, the detector circuit 1033 is exemplified as outputting the control signals S1001, S1002, S1003, and S1004 to switch the peak amplifiers 1016, 1017, 1019-1, and 1019-2 to the non-operating state when the amplitude of the high-frequency signal RF1011 is small.

In the sixth embodiment, the detector circuit 1033 receives the high-frequency signal RF1011, but the present disclosure is not limited thereto. The detector circuit 1033 may receive the high-frequency signal RFin instead of the high-frequency signal RF1011.

When the control signals are current signals, as illustrated in FIG. 14, the detector circuit 1033 may output the separate control signals S1001 to S1004 to the peak amplifiers 1016, 1017, 1019-1, and 1019-2, respectively. When the control signals are voltage signals, the detector circuit 1033 may output a single common control signal to the peak amplifiers 1016, 1017, 1019-1, and 1019-2.

In the following, the peak amplifiers including the enable terminal will be described.

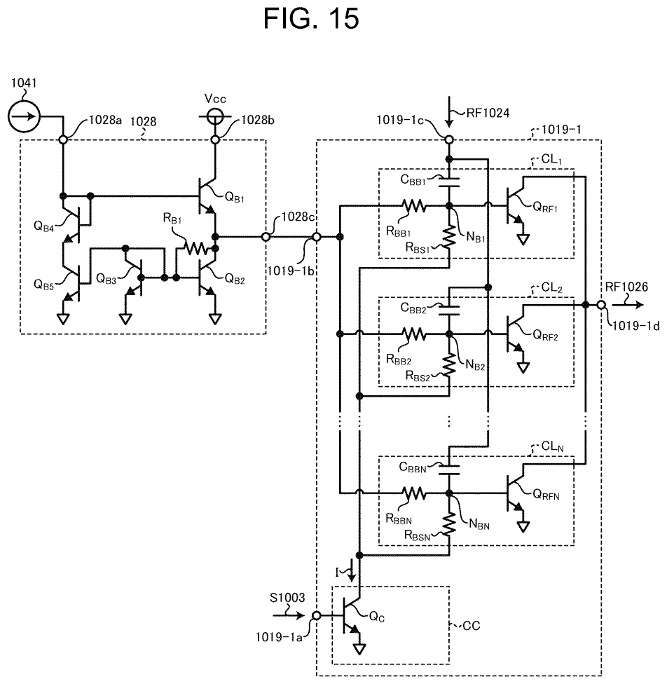

FIG. 15 illustrates a circuit configuration of the peak amplifiers according to the sixth embodiment. FIG. 15 illustrates the final-stage peak amplifier 1019-1 for the first phase as an example of the peak amplifiers included in the Doherty amplifier 1001. However, the other peak amplifiers can be configured in a similar manner.

A terminal 1028a of the bias circuit 1028 receives a constant current from a constant-current source 1041. A terminal 1028b of the bias circuit 1028 is electrically coupled to the power supply potential Vcc.

The bias circuit 1028 includes transistors Q_{B1}, Q_{B2}, Q_{B3}, Q_{B4}, and Q_{B5} and a resistor R_{B1}.

In the sixth embodiment, each transistor is a bipolar transistor. However, the present disclosure is not limited thereto. The bipolar transistors are exemplified as heterojunction bipolar transistors (HBTs), but the present disclosure is not limited thereto. The transistors may be, for example, field-effect transistors (FETs). The transistors may be multi-finger transistors, in which a plurality of unit transistors are electrically coupled in parallel. Each unit transistor refers to the minimum structure that constitutes a transistor.

When each transistor is an FET, the source corresponds to the emitter of the bipolar transistor, the gate corresponds to the base, and the drain corresponds to the collector.

The collector and base of the transistor Q_{B4} are electrically coupled to the terminal 1028a. That is, the transistor Q_{B4} is diode-coupled.

The collector of the transistor Q_{B5} is electrically coupled to the emitter of the transistor Q_{B4}. The emitter of the transistor Q_{B5} is electrically coupled to the reference potential. The reference potential is exemplified as ground potential, but the present disclosure is not limited thereto.

The collector of the transistor Q_{B1} is electrically coupled to the terminal 1028b. The base of the transistor Q_{B1} is electrically coupled to the terminal 1028a and the collector and base of the transistor Q_{B4}. The emitter of the transistor Q_{B1} is electrically coupled to a terminal 1028c of the bias circuit 1028. The transistor Q_{B1} is a transistor that outputs bias voltage or bias current.

The collector of the transistor Q_{B2} is electrically coupled to the emitter of the transistor Q_{B1} and the terminal 28c. The emitter of the transistor Q_{B2} is electrically coupled to the reference potential.

One end of the resistor R_{B1} is electrically coupled to the emitter of the transistor Q_{B1}, the terminal 28c, and the collector of the transistor Q_{B2}. The other end of the resistor R_{B1} is electrically coupled to the base of the transistor Q_{B2}.

The base and collector of the transistor Q_{B3} are electrically coupled to the base of the transistor Q_{B2}, the other end of the resistor R_{B1}, and the base of the transistor Q_{B5}.

The enable terminal 1019-1a of the peak amplifier 1019-1 receives the control signal S3 from the detector circuit 1033 (see FIG. 14). A terminal 1019-1b of the peak amplifier 1019-1 receives bias current or bias voltage from the bias circuit 1028. A terminal 1019-1c of the peak amplifier 1019-1 receives the high-frequency signal RF1024 from the balun 1018 (see FIG. 14). A terminal 1019-1d of the peak amplifier 1019-1 outputs the high-frequency signal RF1026 to the coupler 1020 (see FIG. 14).

The peak amplifier 1019-1 includes cells CL₁, CL₂, . . . , and CL_{N}. That is, the peak amplifier 1019-1 is composed of a multi-finger (multi-cell) transistor including a plurality of cells. However, the present disclosure is not limited thereto. The peak amplifier 1019-1 may be composed of a single-finger (single-cell) transistor including a single cell.

The peak amplifier 1019-1 further includes a state control circuit CC, which switches the cells CL₁, CL₂, . . . , and CL_{N} between the operating state (the high-frequency signal amplified state) and the non-operating state (the high-frequency signal non-amplified state). The state control circuit CC includes a transistor Q_{c}.

The cell CL₁ includes a transistor Q_{RF1}, a capacitor C_{BB1}, and resistors R_{BB1} and R_{BS1}. The transistor Q_{RF1} is exemplified as the unit transistor, but the present disclosure is not limited thereto.

One end of the resistor R_{BB1} is electrically coupled to the terminal 1019-1b. That is, the resistor R_{BB1} is coupled to the transistor Q_{B1} within the bias circuit 1028 as an emitter-follower. The other end of the resistor R_{BB1} is electrically coupled to the node N_{B1}. One end of the capacitor C_{BB1} is electrically coupled to the terminal 1019-1c. The other end of the capacitor C_{BB1} is electrically coupled to the node N_{B1}. The base of the transistor Q_{RF1} is electrically coupled to the node N_{B1}. The emitter of the transistor Q_{RF1} is electrically coupled to the reference potential. The collector of the transistor Q_{RF1} is electrically coupled to the terminal 1019-1d.

The base of the transistor Q_{RF1} receives the bias current or bias voltage via the resistor R_{BB1}. The base of the transistor Q_{RF1} also receives the high-frequency signal RF1024 via the capacitor C_{BB1}. The transistor Q_{RF1} amplifies the high-frequency signal RF1024 and outputs the high-frequency signal RF1026 from the collector to the terminal 1019-1d.

One end of the resistor R_{BS1} is electrically coupled to the node N_{B1}. The other end of the resistor R_{BS1} is electrically coupled to the collector of the transistor Q_{c}.

The cell CL₂ includes a transistor Q_{RF2}, a capacitor C_{BB2}, and resistors R_{BB2} and R_{BS2}. The transistor Q_{RF2} is exemplified as the unit transistor, but the present disclosure is not limited thereto. The connection relationship between the transistor Q_{RF2}, the capacitor C_{BB2}, the node N_{B2}, and the resistors R_{BB2} and R_{BS2} is the same as that between the transistor Q_{RF1}, the capacitor C_{BB1}, the node N_{B1}, and the resistors R_{BB1} and R_{BS1}, and the description thereof is omitted.

The cell CL_{N} includes a transistor Q_{RFN}, a capacitor C_{BBN}, and resistors R_{BBN} and R_{BSN}. The transistor Q_{RFN} is exemplified as the unit transistor, but the present disclosure is not limited thereto. The connection relationship between the transistor Q_{RFN}, the capacitor C_{BBN}, the node N_{BN}, and the resistors R_{BBN} and R_{BSN} is the same as that between the transistor Q_{RF1}, the capacitor C_{BB1}, the node N_{B1}, and the resistors R_{BB1} and R_{BS1}, and the description thereof is omitted.

The collector of the transistor Q_{c} is electrically coupled to the other end of the resistor R_{BS1}, the other end of the resistor R_{BS2}, . . . , and the other end of the resistor R_{BSN}. The base of the transistor Q_{c} is electrically coupled to the enable terminal 19-1a. The base of the transistor Q_{c} receives the control signal S1003. The emitter of the transistor Q_{c} is electrically coupled to the reference potential.

The operation of the state control circuit CC will be described.

When the control signal S1003 is high, the transistor QC is on, and current I flows from the nodes N_{B1}, N_{B2}, . . . , and N_{BN} to the collector of the transistor Q_{C} via the resistors R_{BS1}, R_{BS2}, . . . , R_{BSN}, respectively. That is, the transistor Q_{c} draws the current I from the nodes N_{B1}, N_{B2}, . . . , and N_{BN}.

When current is drawn from the node N_{B1}, a voltage drop occurs across the resistor R_{BB1}, through which the drawn current flows, and the voltage at the node N_{B1} decreases. As a result, the base voltage of the transistor Q_{RF1} decreases, and the transistor Q_{RF1} is unable to amplify the high-frequency signal RF1024.

In a similar manner, when current is drawn from the node N_{B2}, a voltage drop occurs across the resistor R_{BB2}, through which the drawn current flows, and the voltage at the node N_{B2} decreases. As a result, the base voltage of the transistor Q_{RF2} decreases, and the transistor Q_{RF2} is unable to amplify the high-frequency signal RF1024.

In a similar manner, when current is drawn from the node N_{BN}, a voltage drop occurs across the resistor R_{BBN} through which the drawn current flows, and the voltage at the node N_{BN} decreases. As a result, the base voltage of the transistor Q_{RFN} decreases, and the transistor Q_{RFN} is unable to amplify the high-frequency signal RF1024.

That is, when the control signal S1003 goes high, the peak amplifier 1019-1 switches to the non-operating state (the high-frequency signal non-amplified state).

When the control signal S1003 is low, the transistor Q_{C} is off, and the current I does not flow from the nodes N_{B1}, N_{B2}, . . . , and N_{BN} to the collector of the transistor Q_{C}. That is, the transistor Q_{C} does not draw the current I from the nodes N_{B1}, N_{B2}, . . . , and N_{BN}.

As a result, the base voltage of the transistor Q_{RF1} does not decrease, and the transistor Q_{RF1} is able to amplify the high-frequency signal RF1024. In a similar manner, the base voltage of the transistor Q_{RF2} does not decrease, and the transistor Q_{RF2} is able to amplify the high-frequency signal RF1024. In a similar manner, the base voltage of the transistor Q_{RFN} does not decrease, and the transistor Q_{RFN} is able to amplify the high-frequency signal RF1024.

That is, when the control signal S1003 goes low, the peak amplifier 1019-1 switches to the operating state (the high-frequency signal amplified state).

The state control circuit CC may be arranged away from the cells CL₁, CL₂, . . . , and CL_{N}. This is because the current I is less affected by temperature differences. Typically, the detector circuit 1033, which is configured to generate the control signal S1003, is arranged away from the peak amplifiers 1019-1 and 1019-2 as the final-stage amplifier. Therefore, a temperature difference often occurs between the detector circuit 1033 and the peak amplifiers 1019-1 and 1019-2, which are required to output high power and tend to become hot. As a result, the threshold voltage of transistors arranged near the peak amplifiers 1019-1 and 1019-2 tend to be lower than that of transistors arranged near the detector circuit 1033. Here, if the state control circuit CC is arranged near the peak amplifiers 1019-1 and 1019-2, the increased temperature around the peak amplifiers 1019-1 and 1019-2 causes a decrease in the threshold voltage of the transistor Q_{C}, which is included in the state control circuit CC. That is, in the configuration where the state control circuit CC is arranged near the cells CL₁, CL₂, . . . , and CL_{N}, even when the control signal S1003 generated by the detector circuit 1033 is low, the state control circuit CC can mistakenly recognize that “the control signal S1003 is high”. By contrast, in the configuration where the state control circuit CC is arranged away from the cells CL₁, CL₂, . . . , and CL_{N}, the decrease in threshold voltage of the transistor Q_{C}, which is included in the state control circuit CC, can be reduced. This facilitates preventing the misrecognition of the control signal S1003 by the state control circuit CC. For example, the state control circuit CC may be arranged within the control circuit 1021 (see FIG. 14). In this case, the current I can be considered to correspond to the control signal S1003.

The resistor R_{BB1} may be arranged near the transistor Q_{RF1}. This is because voltage tends to be affected by parasitic capacitance. If the resistor R_{BB1} is arranged away from the transistor Q_{RF1}, the influence of the parasitic capacitance delays the transmission of the voltage drop across the resistor R_{BB1} to the base of the transistor Q_{RF1}.

This causes a delay in switching between the operating state and the non-operating state of the transistor Q_{RF1}. In order to accelerate the switching of the transistor Q_{RF1}, the resistor R_{BB1} may be arranged near the transistor Q_{RF1}. The same applies to the other cells.

For example, if the bias circuit 1028 controls the operating state (the high-frequency signal amplified state) and the non-operating state (the high-frequency signal non-amplified state) of the peak amplifier 1019-1 by changing the bias current or bias voltage, like the technique described in U.S. Patent Application Publication No. 2016/0241209 Specification, the switching is delayed. This is because it takes time to change DC current (the bias current) or DC voltage (the bias voltage).

On the other hand, the operating state and non-operating state of the peak amplifier 1019-1 according to the sixth embodiment can be controlled by inputting the control signal S1003, which can be high or low level, to the enable terminal 1019-1a. Therefore, the bias circuit 1028 does not need to change the bias current or bias voltage. As a result, the peak amplifier 1019-1 according to the sixth embodiment can quickly switch between the operating state and the non-operating state.

In the peak amplifier 1019-1 according to the sixth embodiment, the operating state and the non-operating state of the peak amplifier 1019-1 can be controlled by the state control circuit CC drawing the current I from the nodes N_{B1}, N_{B2}, . . . , and N_{BN}. Since the operating state and the non-operating state of the peak amplifier 1019-1 according to the sixth embodiment can be controlled by drawing the current I in this manner, the peak amplifier 1019-1 can switch more quickly than when the operating state and the non-operating state are controlled based on voltage.

In the sixth embodiment, as in FIG. 6, the integrated circuit 4 includes the splitter 1011, the carrier amplifiers 1012, 1013, and 1015, the peak amplifiers 1016, 1017, and 1019, the first bias circuit, the second bias circuit, the drive-level detector circuit 1034, and the detector circuit 1033, which are provided at different positions when viewed in the direction perpendicular to the major surface of the substrate 3. Here, the splitter 1011 corresponds to the splitter 11 in FIG. 6; the carrier amplifiers 1012 and 1015 correspond to the carrier amplifiers 12 and 13 in FIG. 6, respectively; the peak amplifiers 1016 and 1019 correspond to the peak amplifiers 16 and 17 in FIG. 6, respectively; the bias circuit 1022 corresponds to the bias circuit 14 in FIG. 6; the bias circuits 1024 and 1025 correspond to the bias circuit 15 in FIG. 6; the bias circuit 1026 corresponds to the bias circuit 18 in FIG. 6; the bias circuits 1028 and 1029 correspond to the bias circuit 19; the drive-level detector circuit 1034 corresponds to the drive-level detector circuit 26 in FIG. 6; and the detector circuit 1033 corresponds to the detector circuit 22 in FIG. 6. In the sixth embodiment, as in FIG. 6, when viewed in the direction perpendicular to the major surface of the substrate 3, the placement region of the drive-level detector circuit 1034 is adjacent to the placement region where the amplifiers of the carrier amplifier 1015 are arranged. This can reduce the wiring length from the final-stage carrier amplifier 1015 to the drive-level detector circuit 1034, thereby improving the accuracy of detecting instantaneous variations in output of the final-stage carrier amplifier 1015. As a result, the degradation in the quality of high-frequency signals can be suppressed.

As described above, the power amplification device according to the sixth embodiment includes: the substrate 3; the integrated circuit 4, which is provided on the major surface of the substrate 3; the splitter 1011; the carrier amplifiers 1012, 1013, and 1015, which amplify the inputted high-frequency signal RF1011; the peak amplifiers 1016, 1017, and 1019, which amplify an inputted high-frequency signal; the first bias circuit (the bias circuits 1022 to 1025) that provides bias to the carrier amplifiers 1012, 1013, and 1015; the second bias circuit (the bias circuits 1026 to 1029) that provides bias to the peak amplifiers 1016, 1017, and 1019; the drive-level detector circuit 1034, which outputs the signal indicating the drive level of the carrier amplifier 1015, based on the high-frequency signals RF1016 and RF1017 outputted by the carrier amplifier 1015; the detector circuit 1033, which outputs the control signals S1001 to S1004 to control the peak amplifiers 1016, 1017, and 1019, based on the inputted high-frequency signal RF1011 and the signal (the detection signal S1011) indicating the drive level of the carrier amplifier 1015; and the coupler 1020, which is provided on the major surface of the substrate 3. The detector circuit 1033 varies the threshold for the control signal based on the inputted high-frequency signal RF1011 and the signal (the detection signal S1011) indicating the drive level of the carrier amplifier. The integrated circuit 4 includes the splitter 1011, the carrier amplifiers 1012, 1013, and 1015, the peak amplifiers 1016, 1017, and 1019, the first bias circuit, the second bias circuit, the drive-level detector circuit 1034, and the detector circuit 1033, which are provided at different positions when viewed in the direction perpendicular to the major surface of the substrate 3. When viewed in the direction perpendicular to the major surface of the substrate 3, the placement region of the drive-level detector circuit 1034 is adjacent to the placement region where the amplifiers of the carrier amplifier 1015 are arranged.

In this case as well, the wiring length from the final-stage carrier amplifier 1015 to the drive-level detector circuit 1034 can be reduced, thereby improving the accuracy of detecting instantaneous variations in the output of the final-stage carrier amplifier 1015. As a result, the degradation in the quality of high-frequency signals can be suppressed.

### Seventh Embodiment

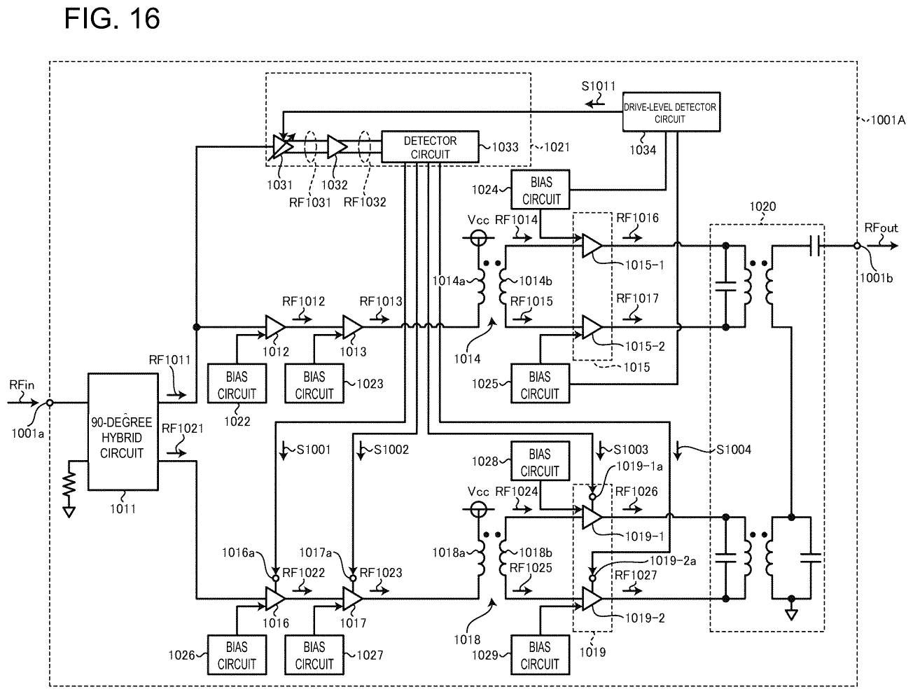

FIG. 16 illustrates a circuit configuration of a power amplification device according to a seventh embodiment. The seventh embodiment differs from the sixth embodiment in that the drive-level detector circuit 1034 outputs the detection signal S1011 based on high-frequency signals outputted by the bias circuits 1024 and 1025. In the seventh embodiment, the control circuit 1021 includes a variable attenuator 1031, an attenuator 1032, and the detector circuit 1033.

In the seventh embodiment, the splitter 1011 outputs the high-frequency signal RF1011 to the carrier amplifier 1012 and the variable attenuator 1031 and outputs the high-frequency signal RF1021 to the peak amplifier 1016.

The drive-level detector circuit 1034 detects the drive level (the operating level) of the carrier amplifier 1015 based on the high-frequency signals outputted by the bias circuits 1024 and 1025. The drive-level detector circuit 1034 outputs the detection signal S1011 indicating the drive level of the carrier amplifier 1015 to the variable attenuator 1031.

The variable attenuator 1031 receives the high-frequency signal RF1011 and the detection signal S1011. The variable attenuator 1031 may receive the high-frequency signal RFin instead of the high-frequency signal RF1011.

The variable attenuator 1031 attenuates and transforms the high-frequency signal RF1011 into a differential signal based on the detection signal S1011 and outputs the resulting signal as a differential high-frequency signal RF1031 to the attenuator 1032. For example, when the detection signal S1011 indicates that the carrier amplifier 1015 is close to saturation, the variable attenuator 1031 is exemplified as outputting the high-frequency signal RF1031 without significantly attenuating the high-frequency signal RF1011. Furthermore, for example, when the detection signal S1011 indicates that the carrier amplifier 1015 is not close to saturation, the variable attenuator 1031 is exemplified as significantly attenuating the high-frequency signal RF1011 to output the high-frequency signal RF1031.

In the seventh embodiment, the variable attenuator 1031 outputs the differential high-frequency signal RF1031. However, the present disclosure is not limited thereto. The variable attenuator 1031 may output a single-ended high-frequency signal. The variable attenuator 1031 may be a variable gain amplifier. In this case, the variable gain amplifier may be controlled based on the amount of amplification (gain), instead of the amount of attenuation.

The attenuator 1032 attenuates the differential high-frequency signal RF1031 and outputs a differential high-frequency signal RF1032 to the detector circuit 1033.

In the seventh embodiment, the attenuator 1032 outputs the differential high-frequency signal RF1032. However, the present disclosure is not limited thereto. The attenuator 1032 may output a single-ended high-frequency signal. The attenuator 1032 may be eliminated if the variable attenuator 1031 provides sufficient attenuation.

The detector circuit 1033, respectively, outputs the control signals S1001, S1002, S1003, and S1004 to the peak amplifiers 1016, 1017, 1019-1, and 1019-2 based on the high-frequency signal RF1032. For example, when the amplitude of the high-frequency signal RF1032 is large, the detector circuit 1033 is exemplified as outputting the control signals S1001, S1002, S1003, and S1004 to switch the peak amplifiers 1016, 1017, 1019-1, and 1019-2 to the operating state. Furthermore, for example, when the amplitude of the high-frequency signal RF1032 is small, the detector circuit 1033 is exemplified as outputting the control signals S1001, S1002, S1003, and S1004 to switch the peak amplifiers 1016, 1017, 1019-1, and 1019-2 to the non-operating state.

In the seventh embodiment, as in FIG. 9, the integrated circuit 4 includes the splitter 1011, the carrier amplifiers 1012, 1013, and 1015, the peak amplifiers 1016, 1017, and 1019, the first bias circuit, the second bias circuit, the drive-level detector circuit 1034, and the detector circuit 1033, which are provided at different positions when viewed in the direction perpendicular to the major surface of the substrate 3. Here, the splitter 1011 corresponds to the splitter 11 in FIG. 9; the carrier amplifiers 1012 and 1015 correspond to the carrier amplifiers 12 and 13 in FIG. 9, respectively; the peak amplifiers 1016 and 1019 correspond to the peak amplifiers 16 and 17 in FIG. 9, respectively; the bias circuit 1022 corresponds to the bias circuit 14 in FIG. 9; the bias circuits 1024 and 1025 correspond to the bias circuit 15 in FIG. 9; the bias circuit 1026 corresponds to the bias circuit 18 in FIG. 9; the bias circuits 1028 and 1029 correspond to the bias circuit 19; the drive-level detector circuit 1034 corresponds to the drive-level detector circuit 26 in FIG. 9; and the detector circuit 1033 corresponds to the detector circuit 22 in FIG. 9. In the seventh embodiment, as in FIG. 9, when viewed in the direction perpendicular to the major surface of the substrate 3, when viewed in the direction perpendicular to the major surface of the substrate 3, the placement region of the drive-level detector circuit 1034 is adjacent to the placement region where the amplifiers of the carrier amplifier 1015 are arranged. This can reduce the wiring length from the first bias circuit to the drive-level detector circuit 1034, thereby improving the accuracy of detecting instantaneous variations in the output of the first bias circuit. As a result, the degradation in the quality of high-frequency signals can be suppressed.

As described above, the power amplification device according to the seventh embodiment includes: the substrate 3; the integrated circuit 4, which is provided on the major surface of the substrate 3; the splitter 1011; the carrier amplifiers 1012, 1013, and 1015, which amplify the inputted high-frequency signal RF1011; the peak amplifiers 1016, 1017, and 1019, which amplify the inputted high-frequency signal RF1021; the first bias circuit (the bias circuits 1022 to 1025) that provides bias to the carrier amplifiers 1012, 1013, and 1015; the second bias circuit (the bias circuits 1026 to 1029) that provides bias to the peak amplifiers; the drive-level detector circuit 1034, which outputs the signal (the detection signal S1011) indicating the drive level of the carrier amplifier 1015, based on the high-frequency signal outputted by the first bias circuit; the control circuit 1021; and the coupler 1020, which is provided on the major surface of the substrate 3. The integrated circuit 4 includes the splitter 1011, the carrier amplifiers 1012, 1013, and 1015, the peak amplifiers 1016, 1017, and 1019, the first bias circuit, the second bias circuit, the drive-level detector circuit 1034, and the control circuit 1021, which are provided at different positions when viewed in the direction perpendicular to the major surface of the substrate 3. The control circuit 1021 includes: the detector circuit 1033, which outputs the control signals S1001 to S1004 to control the peak amplifiers 1016, 1017, and 1019; and the variable attenuator 1031, which outputs to the detector circuit 1033, based on the high-frequency signal RF1011 inputted to the carrier amplifier and the signal (the detection signal S1011) indicating the drive level of the carrier amplifier, the high-frequency signal RF1031, which is obtained by attenuating the inputted high-frequency signal RF1011. When viewed in the direction perpendicular to the major surface of the substrate 3, the placement region of the drive-level detector circuit 1034 is adjacent to the placement region where the amplifiers of the carrier amplifier 1015 are arranged.

As a result, the wiring length from the first bias circuit to the drive-level detector circuit 1034 can be reduced. This can improve the accuracy of detecting instantaneous variations in the output of the first bias circuit, thereby suppressing the degradation in the quality of high-frequency signals.

The embodiments described above are intended to facilitate the understanding of the present disclosure and are not intended to be construed as limiting the present disclosure. The present disclosure may be changed/improved without departing from the spirit thereof and includes the equivalents thereof.

The present disclosure can also take the following aspects.
(1) A power amplification device, including: a substrate; a splitter; an integrated circuit provided on a major surface of the substrate; a carrier amplifier that amplifies an inputted high-frequency signal; a peak amplifier that amplifies an inputted high-frequency signal; a first bias circuit that provides bias to the carrier amplifier; a second bias circuit that provides bias to the peak amplifier; a drive-level detector circuit that outputs a signal indicating a drive level of the carrier amplifier, based on a high-frequency signal outputted by the carrier amplifier; a detector circuit that outputs a control signal to control the second bias circuit, based on an inputted high-frequency signal and the signal indicating the drive level of the carrier amplifier; and a coupler provided on the major surface of the substrate, in which the detector circuit varies a threshold for the control signal based on the inputted high-frequency signal and the signal indicating the drive level of the carrier amplifier, the integrated circuit includes the splitter, the carrier amplifier, the peak amplifier, the first bias circuit, the second bias circuit, the drive-level detector circuit, and the detector circuit, which are provided at different positions when viewed in a direction perpendicular to the major surface of the substrate, and when viewed in the direction perpendicular to the major surface of the substrate, a placement region of the drive-level detector circuit is adjacent to a placement region where an amplifier of the final-stage carrier amplifier is arranged.
(2) A power amplification device, including: a substrate; an integrated circuit provided on a major surface of the substrate; a splitter; a carrier amplifier that amplifies an inputted high-frequency signal; a peak amplifier that amplifies an inputted high-frequency signal; a first bias circuit that provides bias to the carrier amplifier; a second bias circuit that provides bias to the peak amplifier; a drive-level detector circuit that outputs a signal indicating a drive level of the carrier amplifier, based on a high-frequency signal outputted by the carrier amplifier; a detector circuit that outputs a control signal to control the peak amplifier, based on an inputted high-frequency signal and the signal indicating the drive level of the carrier amplifier; and a coupler provided on the major surface of the substrate, in which the detector circuit varies a threshold for the control signal based on the inputted high-frequency signal and the signal indicating the drive level of the carrier amplifier, the integrated circuit includes the splitter, the carrier amplifier, the peak amplifier, the first bias circuit, the second bias circuit, the drive-level detector circuit, and the detector circuit, which are provided at different positions when viewed in a direction perpendicular to the major surface of the substrate, and when viewed in the direction perpendicular to the major surface of the substrate, a placement region of the drive-level detector circuit is adjacent to a placement region where an amplifier of the carrier amplifier is arranged.
(3) The power amplification device according to (1) or (2), in which a high-frequency signal inputted from outside or the high-frequency signal inputted to the carrier amplifier is inputted to the detector circuit.
(4) A power amplification device, including: a substrate; an integrated circuit provided on a major surface of the substrate; a splitter; a carrier amplifier that amplifies an inputted high-frequency signal; a peak amplifier that amplifies an inputted high-frequency signal; a first bias circuit that provides bias to the carrier amplifier; a second bias circuit that provides bias to the peak amplifier; a drive-level detector circuit that outputs a signal indicating a drive level of the carrier amplifier, based on a high-frequency signal outputted by the first bias circuit; a control circuit; and a coupler provided on the major surface of the substrate, in which the integrated circuit includes the splitter, the carrier amplifier, the peak amplifier, the first bias circuit, the second bias circuit, the drive-level detector circuit, and the control circuit, which are provided at different positions when viewed in a direction perpendicular to the major surface of the substrate, the control circuit includes a detector circuit that outputs a control signal to control the second bias circuit, and a variable attenuator that outputs to the detector circuit, based on the high-frequency signal inputted to the carrier amplifier and the signal indicating the drive level of the carrier amplifier, a high-frequency signal obtained by attenuating the inputted high-frequency signal, and when viewed in the direction perpendicular to the major surface of the substrate, a placement region of the drive-level detector circuit is adjacent to a placement region where an amplifier of the final-stage carrier amplifier is arranged.
(5) A power amplification device, including: a substrate; an integrated circuit provided on a major surface of the substrate; a splitter; a carrier amplifier that amplifies an inputted high-frequency signal; a peak amplifier that amplifies an inputted high-frequency signal; a first bias circuit that provides bias to the carrier amplifier; a second bias circuit that provides bias to the peak amplifier; a drive-level detector circuit that outputs a signal indicating a drive level of the carrier amplifier, based on a high-frequency signal outputted by the first bias circuit; a control circuit; and a coupler provided on the major surface of the substrate, in which the integrated circuit includes the splitter, the carrier amplifier, the peak amplifier, the first bias circuit, the second bias circuit, the drive-level detector circuit, and the control circuit, which are provided at different positions when viewed in a direction perpendicular to the major surface of the substrate, the control circuit includes a detector circuit that outputs a control signal to control the peak amplifier, and a variable attenuator that outputs to the detector circuit, based on the high-frequency signal inputted to the carrier amplifier and the signal indicating the drive level of the carrier amplifier, a high-frequency signal obtained by attenuating the inputted high-frequency signal, and when viewed in the direction perpendicular to the major surface of the substrate, a placement region of the drive-level detector circuit is adjacent to a placement region where an amplifier of the carrier amplifier is arranged.
(6) The power amplification device according to any one of (1) to (5), in which the carrier amplifier includes: a first-stage carrier amplifier that amplifies the inputted high-frequency signal, and a final-stage carrier amplifier that amplifies a high-frequency signal outputted from the first-stage carrier amplifier, the peak amplifier includes: a first-stage peak amplifier that amplifies the inputted high-frequency signal; and a final-stage peak amplifier that amplifies a high-frequency signal outputted from the first-stage peak amplifier, and when viewed in the direction perpendicular to the major surface of the substrate, the placement region of the drive-level detector circuit is adjacent to a placement region where an amplifier of the final-stage carrier amplifier is arranged.
(7) The power amplification device according to (6), in which when viewed in the direction perpendicular to the major surface of the substrate, the placement region of the drive-level detector circuit is located between the placement region where the amplifier of the final-stage carrier amplifier is arranged and the placement region where an amplifier of the final-stage peak amplifier is arranged.
(8) The power amplification device according to (6), in which the final-stage carrier amplifier is a differential amplifier including a first amplifier and a second amplifier, and the placement region of the drive-level detector circuit is located between a placement region where the first amplifier is arranged and a placement region where the second amplifier is arranged.
(9) The power amplification device according to any one of (6) to (8), in which when viewed in the direction perpendicular to the major surface of the substrate, a placement region of the detector circuit is located between a placement region where an amplifier of the first-stage carrier amplifier is arranged and a placement region where an amplifier of the first-stage peak amplifier is arranged.
(10) The power amplification device according to any one of (6) to (8), in which when viewed in the direction perpendicular to the major surface of the substrate, a distance from a placement region of the detector circuit to a placement region where an amplifier of the first-stage carrier amplifier is arranged is less than a distance from the detector circuit to the placement region where the amplifier of the final-stage carrier amplifier is arranged, and is greater than a distance from the detector circuit to a placement region where an amplifier of the first-stage peak amplifier is arranged.
(11) The power amplification device according to any one of (6) to (8), in which when viewed in the direction perpendicular to the major surface of the substrate, a distance from a placement region of the detector circuit to a placement region where an amplifier of the first-stage carrier amplifier is arranged is less than a distance from the detector circuit to the placement region where the amplifier of the final-stage carrier amplifier is arranged, and is less than a distance from the detector circuit to a placement region where an amplifier of the first-stage peak amplifier is arranged.
1, 1A to 1D power amplification device
3 substrate
4 integrated circuit
14, 15, 18, 19, 73, 74, 77, 78, 1022 to 1029 bias circuit
11, 1011 splitter
12, 13, 13A, 1012, 1013, 1015 carrier amplifier
16, 17, 17A, 1016, 1017, 1019 peak amplifier
1014, 1018 balun
20, 1020 coupler
21, 1021 control circuit
22, 1033 detector circuit
23, 1031 variable attenuator
1032 attenuator
24, 25 matching circuit
26, 1034 drive-level detector circuit
61, 62 divider
71, 75 first amplifier
72, 76 second amplifier

1. A power amplification device, comprising:
a substrate;
an integrated circuit on a major surface of the substrate;
a splitter;
a carrier amplifier configured to amplify an inputted high-frequency signal;
a peak amplifier configured to amplify the inputted high-frequency signal;
a first bias circuit configured to provide bias to the carrier amplifier;
a second bias circuit configured to provide bias to the peak amplifier;
a drive-level detector circuit configured to output a signal indicating a drive level of the carrier amplifier, based on a high-frequency signal outputted by the carrier amplifier;
a detector circuit configured to output a control signal configured to control the second bias circuit or the peak amplifier, based on the inputted high-frequency signal and the signal indicating the drive level of the carrier amplifier; and
a coupler on the major surface of the substrate,
wherein the detector circuit is configured to vary a threshold for the control signal based on the inputted high-frequency signal and the signal indicating the drive level of the carrier amplifier,
wherein the integrated circuit comprises the splitter, the carrier amplifier, the peak amplifier, the first bias circuit, the second bias circuit, the drive-level detector circuit, and the detector circuit, which are at different positions when viewed in a direction perpendicular to the major surface of the substrate, and
wherein, when viewed in the direction perpendicular to the major surface of the substrate, the drive-level detector circuit is adjacent to an amplifier of the carrier amplifier.

2. The power amplification device according to claim 1, wherein a high-frequency signal external to the power amplification device or the high-frequency signal inputted to the carrier amplifier is inputted to the detector circuit.

3. A power amplification device, comprising:
a substrate;
an integrated circuit on a major surface of the substrate;
a splitter;
a carrier amplifier configured to amplify an inputted high-frequency signal;
a peak amplifier configured to amplify the inputted high-frequency signal;
a first bias circuit configured to provide bias to the carrier amplifier;
a second bias circuit configured to provide bias to the peak amplifier;
a drive-level detector circuit configured to output a signal indicating a drive level of the carrier amplifier, based on a high-frequency signal outputted by the first bias circuit;
a control circuit; and
a coupler on the major surface of the substrate,
wherein the integrated circuit comprises the splitter, the carrier amplifier, the peak amplifier, the first bias circuit, the second bias circuit, the drive-level detector circuit, and the control circuit, which are at different positions when viewed in a direction perpendicular to the major surface of the substrate,
wherein the control circuit comprises:
a detector circuit configured to output a control signal configured to control the second bias circuit or the peak amplifier, and
a variable attenuator configured to output to the detector circuit, based on the high-frequency signal inputted to the carrier amplifier and the signal indicating the drive level of the carrier amplifier, a high-frequency signal obtained by attenuating the inputted high-frequency signal, and
wherein, when viewed in the direction perpendicular to the major surface of the substrate, the drive-level detector circuit is adjacent to an amplifier of the carrier amplifier.

4. The power amplification device according to claim 1,
wherein the carrier amplifier comprises a first-stage carrier amplifier configured to amplify the inputted high-frequency signal, and a final-stage carrier amplifier configured to amplify a high-frequency signal outputted from the first-stage carrier amplifier,
wherein the peak amplifier comprises a first-stage peak amplifier configured to amplify the inputted high-frequency signal; and a final-stage peak amplifier configured to amplify a high-frequency signal outputted from the first-stage peak amplifier, and
wherein, when viewed in the direction perpendicular to the major surface of the substrate, the drive-level detector circuit is adjacent to an amplifier of the final-stage carrier amplifier.

5. The power amplification device according to claim 3,
wherein the carrier amplifier comprises a first-stage carrier amplifier configured to amplify the inputted high-frequency signal, and a final-stage carrier amplifier configured to amplify a high-frequency signal outputted from the first-stage carrier amplifier,
wherein the peak amplifier comprises a first-stage peak amplifier configured to amplify the inputted high-frequency signal; and a final-stage peak amplifier configured to amplify a high-frequency signal outputted from the first-stage peak amplifier, and
wherein, when viewed in the direction perpendicular to the major surface of the substrate, the drive-level detector circuit is adjacent to an amplifier of the final-stage carrier amplifier.

6. The power amplification device according to claim 4, wherein, when viewed in the direction perpendicular to the major surface of the substrate, the drive-level detector circuit is located between the amplifier of the final-stage carrier amplifier and the final-stage peak amplifier.

7. The power amplification device according to claim 5, wherein, when viewed in the direction perpendicular to the major surface of the substrate, the drive-level detector circuit is located between the amplifier of the final-stage carrier amplifier and the final-stage peak amplifier.

8. The power amplification device according to claim 4,
wherein the final-stage carrier amplifier is a differential amplifier comprising a first amplifier and a second amplifier, and
wherein the drive-level detector circuit is located between the first amplifier and the second amplifier.

9. The power amplification device according to claim 5,
wherein the final-stage carrier amplifier is a differential amplifier comprising a first amplifier and a second amplifier, and
wherein the drive-level detector circuit is located between the first amplifier and the second amplifier.

10. The power amplification device according to claim 4, wherein, when viewed in the direction perpendicular to the major surface of the substrate, the detector circuit is located between an amplifier of the first-stage carrier amplifier and an amplifier of the first-stage peak amplifier.

11. The power amplification device according to claim 5, wherein, when viewed in the direction perpendicular to the major surface of the substrate, the detector circuit is located between an amplifier of the first-stage carrier amplifier and an amplifier of the first-stage peak amplifier.

12. The power amplification device according to claim 4, wherein, when viewed in the direction perpendicular to the major surface of the substrate, a distance from the detector circuit to an amplifier of the first-stage carrier amplifier is less than a distance from the detector circuit to the amplifier of the final-stage carrier amplifier, and is greater than a distance from the detector circuit to an amplifier of the first-stage peak amplifier.

13. The power amplification device according to claim 5, wherein, when viewed in the direction perpendicular to the major surface of the substrate, a distance from the detector circuit to an amplifier of the first-stage carrier amplifier is less than a distance from the detector circuit to the amplifier of the final-stage carrier amplifier, and is greater than a distance from the detector circuit to an amplifier of the first-stage peak amplifier.

14. The power amplification device according to claim 4, wherein, when viewed in the direction perpendicular to the major surface of the substrate, a distance from the detector circuit to an amplifier of the first-stage carrier amplifier is less than a distance from the detector circuit to the amplifier of the final-stage carrier amplifier, and is less than a distance from the detector circuit to an amplifier of the first-stage peak amplifier.

15. The power amplification device according to claim 5, wherein, when viewed in the direction perpendicular to the major surface of the substrate, a distance from the detector circuit to an amplifier of the first-stage carrier amplifier is less than a distance from the detector circuit to the amplifier of the final-stage carrier amplifier, and is less than a distance from the detector circuit to an amplifier of the first-stage peak amplifier.
